(19) United States
(12) Patent Application Publication
(10) Pub. No.: US 2015/0364720 A1
(43) Pub. Date: Dec. 17, 2015

(54) GAS BARRIER FILM

(71) Applicant: Konica Minolta, Inc., Tokyo (JP)

(72) Inventor: Hiroaki ITOH, Tokyo (JP)

(21) Appl. No.: 14/763,699

(22) PCT Filed: Jan. 31, 2014
(86) PCT No.: PCT/JP2014/052324

§ 371 Date: Jul. 27, 2015

(30) Foreign Application Priority Data
Jan. 31, 2013 (JP) 2013-017257

(51) Int. Cl. H01L 51/52; C23C 14/22; C23C 16/44

(52) U.S. Cl. CPC H01L 51/5253; C23C 16/44; C23C 14/22

(57) ABSTRACT

Provided is a gas barrier film with excellent storage stability, in particular, storage stability under harsh conditions (high temperature and high moisture conditions). The present invention provides a gas barrier film including, in order, a substrate, a first barrier layer which contains an inorganic compound, and a second barrier layer which contains at least silicon atoms and oxygen atoms, which has an abundance ratio of oxygen atoms to silicon atoms (O/Si) of 1.4 to 2.2, and which has an abundance ratio of nitrogen atoms to silicon atoms (N/Si) of 0 to 0.4.

### TECHNICAL FIELD

The present invention relates to a gas barrier film. More specifically, it relates to a gas barrier film that is used for electronic devices such as an organic electroluminescence (EL) element, a solar cell element, or a liquid crystal display.

### BACKGROUND ART

Conventionally, a gas barrier film formed by laminating plural layers which include a thin film of a metal oxide such as aluminum oxide, magnesium oxide or silicon oxide formed on a surface of a plastic substrate or a film have been widely used in packaging applications for articles that require blockage of water vapor and various kinds of gases such as oxygen, for example, packaging applications for preventing deterioration of foods, industrial products, pharmaceuticals and the like.

In addition to the packaging applications, a gas barrier film is desired for development into a flexible electronic device such as a solar cell element, an organic electroluminescence (EL) element, or a liquid crystal display element having flexibility, and thus many considerations have been made. However, because a gas barrier property with very high glass substrate level is required for those flexible electronic devices, a gas barrier film having sufficient performance is not obtained at present.

As a method for forming the gas barrier film, a gas phase method such as a chemical deposition method (plasma CVD method: Chemical Vapor Deposition) in which an organic silicon compound represented by tetra ethoxysilane (TEOS) is used and grown on a substrate while performing oxygen plasma oxidation under reduced pressure, or a physical deposition method in which metal Si is evaporated by using semiconductor laser and deposited on a substrate in the presence of oxygen (vacuum vapor deposition method or sputtering method) is known.

The inorganic film forming method based on those gas phase methods are preferably applied for forming an inorganic film of silicon oxide, silicon nitride, silicon oxynitride and the like. Many considerations regarding a composition range of an inorganic film and layer configuration containing those inorganic films are made to obtain a good gas barrier property.

Furthermore, according to the gas phase method described above, it is very difficult to form a film having no defects, and thus it is necessary to suppress an occurrence of defects by lowering a film forming rate to an extreme level, for example. As such, at an industrial level requiring productivity, the gas barrier property that is required for a flexible electronic device is not obtained yet. Considerations have been also made such as simply increasing film thickness of an inorganic film by a gas phase method or laminating plural layers of an inorganic film. However, as the defects continuously grow or cracks are increased, an improvement of a gas barrier property has not been achieved.

In the case of an organic EL element, for example, the defects of an inorganic film cause an occurrence of dark points showing no light emission, which are referred to as dark spots, or increased size of dark spots at high temperature and high moisture conditions, thereby affecting the durability of the element itself.

Meanwhile, in addition to the film forming by a gas phase method until now, as one of the methods for forming a gas barrier layer, studies have been made such that a solution of an inorganic precursor compound is coated on an inorganic film by the aforementioned gas phase method, a coated layer formed by drying the solution is modified by heat to restore effectively a defective part of an inorganic film, which has been formed by the aforementioned gas layer method, and also to improve the gas barrier property by the laminated film itself. In particular, the studies have been made to express a high-level gas barrier property based on restoration of a defect part by using polysilazane as an inorganic precursor compound (for example, WO 2012/014653 A).

However, for forming a dense silicon oxynitride film or silicon oxide film by heat conversion or wet heat conversion of polysilazane, high temperature of 450° C. or higher is necessary so that applications to a flexible substrate such as plastics were not possible to achieve.

As a means for solving those problems, a method of forming a silicon oxynitride film or silicon oxide film by performing vacuum ultraviolet ray irradiation on a coating film formed by coating of a polysilazane solution has been suggested.

It is possible that an oxidation reaction with active oxygen or ozone is performed while directly cutting an atomic bond only via an action of photons called a photon process by employing light energy having a wavelength of 100 to 200 nm called vacuum ultraviolet ray (hereinafter, referred to also as “VUV”, “VUV light”), which has higher energy than the binding force among each atom of polysilazane, to form a silicon oxynitride film or silicon oxide film at relatively low temperature.

Specifically, in general, when polysilazane is coated on a resin film substrate and performing ultraviolet ray irradiation, a barrier layer (high concentration nitrogen layer) is formed according to conversion of a surface region near the irradiated surface. It has been reported that oxidizing behavior simultaneously occurs presumably due to moisture incorporation from a substrate side and the inside under the barrier layer turns into an oxide film (silicon oxide layer) (see, WO 2011/007543 A, for example).

Furthermore, a method of controlling film composition based on addition amount of amine(JP 2012-16854 A, for example), or a method of promoting the reaction in advance by adding in advance alcohols or the like to a coating liquid of polysilazane (see, Japanese Patent No. 3212400, for example) is disclosed.

### SUMMARY OF THE INVENTION

However, according to the techniques described in the aforementioned Patent Literatures, the barrier layer (gas barrier layer) may be deteriorated by hydrolysis at high temperature and high moisture conditions, although it remains intact for long term storage at conditions with not so high temperature but high moisture. As a result, there is a problem of having gradual decrease in the gas barrier property. In particular, the problem is significant for a gas barrier film having two or more layers of a barrier layer (gas barrier layer).

The present invention is devised under the circumstances described above, and object of the invention is to provide a gas barrier film with excellent storage stability, in particular, storage stability under harsh conditions (high temperature and high moisture conditions).

Inventors of the present invention conducted intensive studies to solve the aforementioned problems. As a result, it was found that the problems can be solved by a gas barrier film including a first barrier layer which contains an inorganic compound and a second barrier layer in which an abundance ratio of oxygen atoms to silicon atoms is within a specific range and an abundance ratio of nitrogen atoms to silicon atoms is within a specific range. The present invention is completed accordingly.

Specifically, the present invention relates to a gas barrier film including, in order, a substrate, a first barrier layer which contains an inorganic compound, and a second barrier layer which contains at least silicon atoms and oxygen atoms, which has an abundance ratio of oxygen atoms to silicon atoms (O/Si) of 1.4 to 2.2 and an abundance ratio of nitrogen atoms to silicon atoms (N/Si) of 0 to 0.4.

### BRIEF DESCRIPTION OF THE DRAWINGS

FIG. 1 is a schematic drawing illustrating an exemplary vacuum plasma CVD apparatus used for forming the first barrier layer according to the present invention. 101 represents a plasma CVD apparatus, 102 represents a vacuum chamber, 103 represents a cathode electrode, 105 represents a susceptor, 106 represents a heat medium circulation system, 107 represents a vacuum evacuation system, 108 represents a gas introduction system, 109 represents a high frequency power source, 110 represents a substrate, and 160 represent a heating and cooling device.

FIG. 2 is a schematic drawing illustrating an example of another manufacturing apparatus which is used for forming the first barrier layer according to the present invention. 1 represents a gas barrier film, 2 represents a substrate, represents a first barrier layer, 31 represents a manufacturing apparatus, 32 represents a feed roller, 33, 34, 35, and 36 represent a conveying roller, 39 and 40 represent a film forming roller, 41 represents a gas supplying pipe, 42 represents a power source for generating plasma, 43 and 44 represent a device for generating magnetic field, and 45 represents a take-up roller.

FIG. 3 is a schematic drawing illustrating an example of a vacuum ultraviolet ray illuminator, in which 21 represents an apparatus chamber, 22 represents a Xe excimer lamp, 23 represents a holder, 24 represents a sample stage, 25 represents a sample, and 26 represents a light blocking plate.

### DETAILED DESCRIPTION

The present invention is a gas barrier film including, in order: a substrate; a first barrier layer which contains an inorganic compound; and a second barrier layer which contains at least silicon atoms and oxygen atoms, which has an abundance ratio of oxygen atoms to silicon atoms (O/Si) of 1.4 to 2.2, and which has an abundance ratio of nitrogen atoms to silicon atoms (N/Si) of 0 to 0.4.

By having this constitution, a gas barrier film with excellent storage stability for a long period of time, in particular, storage stability under harsh conditions such as high temperature and high moisture conditions can be obtained.

Although the detailed reason remains unclear, it is believed that the reason why the gas barrier film of the present invention has excellent storage stability, in particular, storage stability at high temperature and high moisture conditions is as described below.

The chemical composition of a barrier layer containing at least silicon atoms and oxygen atoms, in particular, a barrier layer obtained by conversion of a layer containing polysilazane, includes a non-bonding arm in the silicon atoms. When there are dangling bond, Si—OH, Si—H, and Si radical at high temperature and high moisture conditions, such non-bonding arm is present in the form which is easily affected by hydrolysis. To lower such influence, it is important to reduce as much as possible the non-bonding arm in silicon atoms. In this regard, according to the composition of the second barrier layer of the present invention, the non-bonding arm in silicon atoms is reduced so that it is difficult to have phenomena such as a change in chemical composition or a decrease in film density accompanying the hydrolysis during storage at high temperature and high moisture conditions. Thus, a gas barrier film having excellent storage stability is obtained. The gas barrier film of the present invention has a constitution with at least two barrier layers. Even with such constitution, a gas barrier film having excellent storage stability is obtained. It is also known that the long term storage stability, in particular, storage stability under harsh conditions of high temperature and high moisture, is significantly lowered with a constitution in which at least one barrier layer containing an inorganic compound is included in a lower layer. According to such constitution, a gas barrier film having excellent storage stability under harsh conditions of high temperature and high moisture conditions is obtained in the present invention.

Meanwhile, the aforementioned mechanism is just presumption and the present invention is not limited at all to that mechanism.

Hereinbelow, the preferred embodiments of the present invention are described. However, the present invention is not limited to the following embodiments.

Furthermore, as described herein, “X to Y” representing a range means “X or more and Y or less” and “weight” and “mass”, “% by weight” and “% by mass”, and “parts by weight” and “parts by mass” are treated as synonyms. Furthermore, unless specifically described otherwise, the operations and measurements of physical properties are performed under conditions of room temperature (20 to 25° C.)/relative humidity of 40 to 50%.

<Gas Barrier Film>

The gas barrier film of the present invention has a substrate, a first barrier layer, and a second barrier layer in order. The gas barrier film of the present invention may further contain other member. The gas barrier film of the present invention may contain other member, for example, between a substrate and a first barrier layer, between a first layer and a second layer, on top of a second layer, or on the other surface of a substrate on which a first barrier layer or a second barrier layer is not formed. Herein, other member is not particularly limited, and a member used for a gas barrier film of a related art can be similarly used or it can be used after suitable modification. Specific examples thereof include an intermediate layer, a protective layer, a smooth layer, an anchor coat layer, a bleed out preventing layer, a desiccant layer having moisture adsorptivity, and a functionalized layer such as an antistatic layer.

A gas barrier unit having a first barrier layer and a second barrier layer may be formed on one surface of a substrate or both surfaces of a substrate. Furthermore, the gas barrier unit may also include a layer which does not necessarily have a gas barrier property.

[Substrate]

In the gas barrier film of the present invention, a plastic film or a plastic sheet is preferably used as a substrate, and a film or a sheet consisting of a colorless and transparent resin is more preferably used. The plastic film to be used is not particularly limited in terms of a material and thickness as long as it can support a first barrier layer and a second barrier layer, and it can be suitably selected depending on purpose of use or the like. Specific examples of the plastic film include a thermoplastic resin such as a polyester resin, a methacryl resin, a methacrylic acid-maleic acid copolymer, a polystyrene resin, a transparent fluororesin, polyimide, a fluorinated polyimide resin, a polyamide resin, a polyamide imide resin, a polyether imide resin, a cellulose acylate resin, a polyurethane resin, a polyether ether ketone resin, a polycarbonate resin, an alicyclic polyolefin resin, a polyarylate resin, a polyether sulfone resin, a polysulfone resin, a cycloolefin copolymer, a fluorene ring-modified polycarbonate resin, an alicyclic modified polycarbonate resin, a fluorene ring-modified polyester resin, or an acryloyl compound.

When the gas barrier film according to the present invention is used as a substrate of an electronic device such as an organic EL element, the substrate preferably consists of a material with heat resistance. Specifically, a substrate having linear expansion coefficient of 15 ppm/K or more and 100 ppm/K or less and glass transition temperature (Tg) of 100° C. or higher and 300° C. or lower is used.

When the gas barrier film according to the present invention is used in combination with a polarizing plate, for example, it is preferable to have an arrangement such that the barrier layer of a gas barrier film faces the inside of a cell. More preferably, the arrangement is made such that the barrier layer of a gas barrier film is present on the innermost side of a cell (adjacent to an element).

From the viewpoint of use as an electronic device such as an organic EL element, the substrate of the gas barrier film according to the present invention is preferably transparent. In other words, the light transmittance is generally 80% or more, preferably 85% or more, and more preferably 90% or more. The light transmittance can be obtained according to the method described in JIS K7105: 1981, that is, total light transmittance and scattered light amount are measured by using an integration sphere type transmittance-measuring apparatus and it can be obtained by subtracting diffused transmittance from the total light transmittance.

Meanwhile, even when the gas barrier film according to the present invention is used for display application, the transparency is not always required if it is not installed on an observation side or the like. As such, an opaque material can be used as a substrate for such case. Examples of the opaque material include polyimide, polyacrylonitrile, and a known liquid crystal polymer.

Thickness of the substrate which is used for the gas barrier film according to the present invention is not particularly limited as it is suitably selected depending on use. However, it is typically 1 to 800 μm, and preferably 10 to 200 μm. The plastic film may also include a functional layer such as a transparent conductive layer, a primer layer, and a clear hard coat layer. With regard to the functional layer, those described in paragraphs “0036” to “0038” of JP 2006-289627 A can be suitably employed in addition to those described above.

The substrate preferably has a surface with high smoothness. With regard to the smoothness of a surface, average surface roughness (Ra) is preferably 2 nm or less. Although it is not particularly limited, the lower limit is 0.01 nm or higher from the viewpoint of actual use. If necessary, it is possible that both surface of a substrate or at least a surface for forming the barrier layer is polished to enhance the smoothness.

Furthermore, the aforementioned substrate can be either a non-stretched film or a stretched film.

The substrate to be used in the present invention can be produced by a previously well-known general method. For example, by melting a resin as a material by an extruder, and extruding the molten resin through a ring die or a T-die followed by rapid cooling, an unstretched substrate, which is substantially amorphous and is not oriented, can be produced.

At least a substrate surface for forming a first barrier layer according to the present invention can be subjected to various known treatments for improving adhesiveness, for example, a corona discharge treatment, a flame treatment, an oxidation treatment, or a plasma treatment, or lamination of a smooth layer that is described below. If necessary, those treatments are preferably performed in combination.

[First Barrier Layer]

A first barrier layer according to the present invention which is formed on top of a substrate contains an inorganic compound. Examples of the inorganic compound to be contained in the first barrier layer include, although not particularly limited, metal oxides, metal nitrides, metal carbides, metal oxynitrides, and metal oxycarbides. Among them, from the viewpoint of the gas barrier performance, oxides, nitrides, carbides, oxynitrides, or oxycarbides containing at least one metal selected from Si, Al, In, Sn, Zn, Ti, Cu, Ce and Ta can be preferably used. Oxides, nitrides, or oxynitrides of a metal selected from Si, Al, In, Sn, Zn and Ti are more preferable. Oxides, nitrides, or oxynitrides of at least one of Si and Al is particularly preferable. Specific example of the preferred inorganic compound include silicon oxide, silicon nitride, silicon oxynitride, silicon carbide, silicon oxycarbide, aluminum oxide, titanium oxide, and a composite such as aluminum silicate. It may contain other element as an additional component.

Content of the inorganic compound to be obtained in a first barrier layer is, although not particularly limited, preferably 50% by weight or more, more preferably 80% by weight or more, even more preferably 95% by weight or more, particularly preferably 98% by weight or more, and most preferably 100% by weight or more in the first barrier layer (the first barrier layer consists of an inorganic compound).

By containing an inorganic compound, the first barrier layer has a gas barrier property. As described herein, the gas barrier property of the first barrier layer is preferably 0.1 g/(m²·day) or less, and more preferably 0.01 g/(m²·day) or less in terms of water vapor transmission rate (WVTR) when calculation is made for a laminate in which the first barrier layer is formed on a substrate.

As for the method for forming a first barrier layer, a vacuum film forming method such as a physical vapor phase growing method (PVD method) and a chemical vapor phase growing method (CVD method) or a method in which a coating film formed by coating a liquid containing an inorganic compound, preferably, a liquid containing a silicon compound, is subjected to a conversion treatment (hereinbelow, also simply referred to as a coating method) is preferable. A physical vapor phase growing method or a chemical vapor phase growing method is more preferable.

Hereinbelow, descriptions are given for the vacuum film forming method and coating method.

<Vacuum Film Forming Method>

The physical vapor phase growing method (Physical Vapor Deposition, PVD method) is a method of depositing a target substance, for example, a thin film such as a carbon film, on a surface of a substance in a vapor phase by a physical procedure, and examples thereof include a sputtering method (DC sputtering, RF sputtering, ion beam sputtering, magnetron sputtering, or the like), a vacuum vapor deposition method, an ion plating method, and the like.

In the sputtering method, a target is arranged in a vacuum chamber, an ionized noble gas element (usually, argon) obtained by applying a high voltage is allowed to collide with the target and atoms on the target surface are sputtered so as to attach to a substrate. In this case, a reactive sputtering method in which, by flowing a nitrogen gas or an oxygen gas in the chamber, an element sputtered from the target by an argon gas is reacted with nitrogen and oxygen so as to form an inorganic layer may also be used.

Meanwhile, the chemical vapor phase growing method (Chemical Vapor Deposition, CVD method) is a method of supplying a raw material gas containing a component of a target thin film to a substrate and depositing a film by chemical reaction on the substrate surface or gas phase. Further, there is a method of generating plasma or the like for the purpose of activating the chemical reaction, and examples thereof include a known CVD method such as a thermal CVD method, a catalyst chemistry vapor phase growing method, a photo CVD method, a vacuum plasma CVD method, and an atmospheric pressure plasma CVD method. Although it is not particularly limited, from the viewpoint of film forming speed and treatment area, it is preferable to apply a plasma CVD method.

The first barrier layer obtained by a vacuum plasma CVD method or a plasma CVD method at or near the atmospheric pressure is preferable in that a target compound can be produced by selecting conditions of a metal oxide compound as a raw material (also referred to as a primary material), decomposition gas, decomposition temperature, input power, and the like.

For example, when a silicon compound is used as a raw material compound and oxygen is used as decomposition gas, silicon oxide is generated, because very active charged particles•active radicals are present at very high density in a plasma space, a multi-step chemical reaction is promoted at very high speed in a plasma space and thus elements present in a plasma space are converted within a very short time to a thermodynamically stable compound.

As a raw material, a silicon compound, a titanium compound, or an aluminum compound is preferably used. The raw material compound can be used either singly or in combination of two or more types.

Among them, examples of the silicon compound include silane, tetra methoxysilane, tetra ethoxysilane, tetra n-propoxysilane, tetra isopropoxysilane, tetra n-butoxysilane, tetra t-butoxysilane, dimethyldimethoxysilane, dimethyldiethoxysilane, diethyldimethoxysilane, diphenyldimethoxysilane, methyltriethoxysilane, ethyltrimethoxysilane, phenyltriethoxysilane, (3,3,3-trifluoropropyl)trimethoxysilane, hexamethyldisiloxane, bis(dimethylamino)dimethylsilane, bis(dimethylamino)methylvinylsilane, bis(ethylamino)dimethylsilane, N,O-bis(trimethylsilyl)acetamide, bis(trimethylsilyl)carbodiimide, diethylaminotrimethylsilane, dimethylaminodimethylsilane, hexamethyldisilazane, hexamethylcyclotrisilazane, heptamethyldisilazane, nonamethyltrisilazane, octamethylcyclotetra silazane, tetra kisdimethylaminosilane, tetra isocyanatesilane, tetra methyldisilazane, tris(dimethylamino)silane, triethoxyfluorosilane, allyldimethylsilane, allyltrimethylsilane, benzyltrimethylsilane, bis(trimethylsilyl)acetylene, 1,4-bistrimethylsilyl-1,3-butadiyne, di-t-butylsilane, 1,3-disilabutane, bis(trimethylsilyl)methane, cyclopentadienyltrimethylsilane, phenyldimethylsilane, phenyltrimethylsilane, propargyltrimethylsilane, tetra methylsilane, trimethylsilylacetylene, 1-(trimethylsilyl)-1-propine, tris(trimethylsilyl)methane, tris(trimethylsilyl)silane, vinyltrimethylsilane, hexamethyldisilane, octamethylcyclotetra siloxane, tetra methylcyclotetra siloxane, hexamethylcyclotetra siloxane, and M silicate 51. Furthermore, mention can be made for a silicon compound which is used as a raw material for forming a barrier layer satisfying the requirements (i) to (iii) that are preferred mode described below.

Examples of the titanium compound include titanium methoxide, titanium ethoxide, titanium isopropoxide, titanium tetra isopropoxide, titanium n-butoxide, titanium isopropoxide(bis-2,4-pentanedionate), titanium diisopropoxide (bis-2,4-ethylacetoacetate), titanium di-n-butoxide (bis-2,4-pentanedionate), titanium aetylacetonate and butyl titanate dimer.

Examples of the aluminum compound include aluminum ethoxide, aluminum triisopropoxide, aluminum isopropoxide, aluminum n-butoxide, aluminum s-butoxide, aluminum t-butoxide, aluminum acetylacetonate and triethyl dialuminum tri-s-butoxide.

Examples of the decomposition gas for decomposing the raw material gas containing the metal to form an inorganic compound include hydrogen gas, methane gas, acetylene gas, carbon monoxide gas, carbon dioxide gas, nitrogen gas, ammonium gas, nitrous oxide gas, nitrogen oxide gas, nitrogen dioxide gas, oxygen gas, and steam. It is also possible that the decomposition gas is mixed with inert gas such as argon gas and helium gas.

By suitably selecting the raw material gas containing a raw material compound and decomposition gas, a desired first barrier layer can be obtained. The first barrier layer formed by a CVD method is a layer which contains oxide, nitride, oxynitride, or oxycarbide.

Hereinbelow, the vacuum plasma CVD method as a preferred mode of CVD method is specifically described.

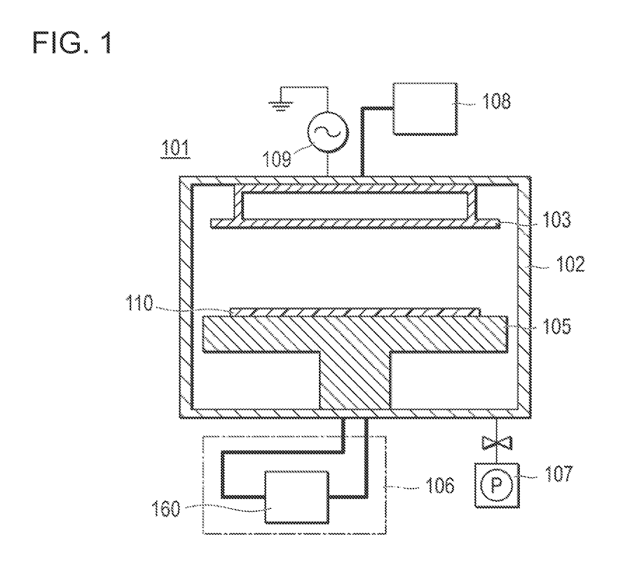

FIG. 1 is a schematic drawing illustrating an exemplary vacuum plasma CVD apparatus used for forming the first barrier layer according to the present invention.

In FIG. 1, the vacuum plasma CVD apparatus 101 has the vacuum chamber 102, and on a bottom surface side inside the vacuum chamber 102, the susceptor 105 is disposed.

Furthermore, on a ceiling side inside the vacuum chamber 102, the cathode electrode 103 is disposed at a position opposite to the susceptor 105. On the outside of the vacuum chamber 102, the heat medium circulation system 106, the vacuum evacuation system 107, the gas introduction system 108, and the high frequency power source 109 are disposed. A heat medium is arranged in the heat medium circulation system 106. On the heat medium circulation system 106, the heating and cooling device 160 having a pump for transferring the heat medium, a heating device for heating the heat medium, a cooling device for cooling, a temperature sensor for measuring the temperature of a heat medium, and a memory device for memory of set temperature of a heating medium is disposed.

The heating and cooling device 160 is constituted such that temperature of a heat medium is measured and, with heating or cooling to a memorized set temperature, the heat medium is supplied to the susceptor 105.

The supplied heat medium flows inside the susceptor 105 to heat or cool the susceptor 105 and then returns to the heating and cooling device 160. In this case, temperature of the heat medium is either higher or lower than the set temperature, and the heat medium is either heated or cooled to the set temperature by the heating and cooling device 160 and then supplied to the susceptor 105. Accordingly, the cooling medium circulates between the susceptor and the heating and cooling device 160, and the susceptor 105 is either heated or cooled by a supplied heat medium at set temperature.

The vacuum chamber 102 is connected to the vacuum evacuation system 107. Before starting a film forming treatment by this vacuum plasma CVD apparatus 101, inside of the vacuum chamber 102 is vacuum-evacuated in advance and also the heat medium is heated from room temperature to a set temperature, and then the heat medium at set temperature is supplied to the susceptor 105. At the beginning of use, the susceptor 105 is at room temperature, but as the heat medium at set temperature is supplied, temperature of the susceptor 105 increases.

After circulation of a heat medium at set temperature for a certain period of time, the substrate 110 as a subject for film forming is introduced to the vacuum chamber 102 and disposed on top of the susceptor 105 while maintaining the vacuum atmosphere within the vacuum chamber 102.

On a surface of the cathode electrode 103 which is opposite to the susceptor 105, several nozzles (holes) are formed.

The cathode electrode 103 is connected to the gas introduction system 108, and when CVD gas is introduced from the gas introduction system. 108 to the cathode electrode 103, CVD gas is released from nozzles of the cathode electrode 103 into the vacuum chamber 102 in vacuum atmosphere.

The cathode electrode 103 is connected to the high frequency power source 109 and the susceptor 105 and the vacuum chamber 102 are connected to ground potential.

When CVD gas is introduced from the gas introduction system 108 to inside of the vacuum chamber 102, the high frequency power source 109 is activated while a heat medium at constant temperature is supplied from the heating and cooling device 160 to the susceptor 105, and high frequency voltage is applied to the cathode electrode 103, plasma of introduced CVD gas is formed. When the CVD gas activated in plasma reaches the surface of the substrate 110 on the susceptor 105, a first barrier layer grows as a thin film on a surface of the substrate 110.

At that time, the distance between the susceptor 105 and the cathode electrode 103 is suitably decided.

Furthermore, the flow amount of the raw material gas and decomposition gas are suitably set with consideration of types of the raw material gas and decomposition gas, or the like. As one embodiment, the flow amount of a raw material gas is 30 to 300 sccm and the flow amount of a decomposition gas is 100 to 1000 sccm.

During growth of a thin film, a heat medium at constant temperature is supplied from the heating and cooling device 160 to the susceptor 105, and as the susceptor 105 is heated or cooled by the heat medium and kept at constant temperature, a thin film is formed. In general, the lower limit temperature of the growth temperature for forming a thin film is determined by film quality of a thin film. The upper limit temperature is determined by an allowed range of damages on a thin film, which are already formed on the substrate 110. The lower limit temperature or upper limit temperature varies depending on a material of a thin film to be formed or a material of a thin film which has been already formed. In order to ensure film quality with high gas barrier property, it is preferable that the lower limit temperature be 50° C. or higher and the upper limit temperature be equal to or lower than the heat resistant temperature of a substrate.

By obtaining in advance the correlationship between the film quality of a thin film formed by a vacuum plasma CVD method and the film forming temperature and the correlationship between the damages occurring on filming subject (substrate 110) and the film forming temperature, the lower limit temperature•the upper limit temperature are decided. For example, temperature of the substrate 110 is preferably 50 to 250° C. during a vacuum plasma CVD process.

Furthermore, as the relationship between the temperature of a heat medium supplied to the susceptor 105 and the temperature of the substrate 110 have been already measured for a case in which plasma is formed by applying high frequency voltage of 13.56 MHz or more to the cathode electrode 103, and to keep the temperature of the substrate 110 at a temperature between the lower limit temperature and the upper limit temperature during a vacuum plasma CVD process, the temperature of the heat medium which is supplied to the susceptor 105 is obtained.

For example, as the lower limit temperature is memorized (herein, it is 50° C.), a setting is made such that a heat medium at a temperature controlled to be equal to or higher than the lower limit temperature is supplied to the susceptor 105. The heat medium refluxed from the susceptor 105 is heated or cooled and a heat medium at set temperature of 50° C. is supplied to the susceptor 105. For example, in a state in which mixture gas containing silane gas, ammonia gas, and nitrogen gas is supplied as CVD gas and the substrate 110 is kept at temperature of between the lower limit temperature and upper limit temperature, SiN film is formed.

Right after operating the vacuum plasma CVD apparatus 101, the susceptor 105 is at room temperature and the temperature of a heat medium refluxed from the susceptor 105 to the heating and cooling device 160 is lower than the set temperature. As such, right after the operation, refluxed heat medium is heated to a set temperature by the heating and cooling device 160 and supplied to the susceptor 105. In that case, the susceptor 105 and the substrate 110 are heated by a heat medium, and the substrate 110 is kept at temperature range of between the lower limit temperature and upper limit temperature.

When a thin film is continuously formed on plural pieces of the substrate 110, temperature of the susceptor 105 increases due to the heat introduced from plasma. In that case, as the heat medium refluxed from the susceptor 105 to the heating and cooling device 160 has higher temperature than the lower limit temperature (50° C.), the heat medium is cooled by the heating and cooling device 160 and the heat medium at a set temperature is supplied to the susceptor 105. Accordingly, a thin film can be formed while maintaining the substrate 110 at a temperature range of between the lower limit temperature and upper limit temperature.

As described above, the heat medium is heated by the heating and cooling device 160 when temperature of the refluxed heat medium is lower than the set temperature while it is cooled by the heating and cooling device 160 when the temperature of the refluxed heat medium is higher than the set temperature, thus the heat medium at set temperature is supplied to a susceptor in any case. As a result, the substrate 110 is kept at a temperature range of between the lower limit temperature and upper limit temperature.

When a thin film is formed to pre-determined film thickness, the substrate 110 is transferred to an outside of vacuum chamber 102, and the substrate 110 not formed in film shape is introduced to vacuum chamber 102 and then a thin film is formed as described above while supplying a heat medium at set temperature.

Furthermore, as one preferred embodiment of the first barrier layer according to the present invention which is formed by a CVD method, the first barrier layer preferably contains carbon, silicon, and oxygen as constitutional elements. More preferred embodiment relates to a layer satisfying the following requirements (i) to (iii).

(i) With regard to a silicon distribution curve showing the relationship between the distance (L) from a surface of the first barrier layer in film thickness direction of the first barrier layer and ratio of the amount of silicon atoms (silicon atomic ratio) relative to total amount of silicon atoms, oxygen atoms and carbon atoms, an oxygen distribution curve showing the relationship between the L and ratio of the amount of oxygen atoms (oxygen atomic ratio) relative to total amount of silicon atoms, oxygen atoms and carbon atoms, and a carbon distribution curve showing the relationship between the L and ratio of the amount of carbon atoms (carbon atomic ratio) relative to total amount of silicon atoms, oxygen atoms and carbon atoms, abundance is high in order of (oxygen atomic ratio), (silicon atomic ratio), (carbon atomic ratio) (atomic ratio of O>Si>C) within at least 90% film thickness region of the first barrier layer (upper limit: 100%);

(ii) the carbon distribution curve has at least two extreme values; and

(iii) the absolute value of a difference between the maximum value and the minimum value of the carbon atomic ratio in the carbon distribution curve (hereinbelow, also simply referred to as “difference of Cₘₐₓ−Cₘᵢₙ^{”}) is 3 at % or more.

Hereinbelow, descriptions are given for the requirements (i) to (iii).

In the first barrier layer, it is preferable that (i) with regard to a silicon distribution curve showing the relationship between the distance (L) from a surface of the first barrier layer in film thickness direction of the first barrier layer and ratio of the amount of silicon atoms (silicon atomic ratio) relative to total amount of silicon atoms, oxygen atoms and carbon atoms, an oxygen distribution curve showing the relationship between the L and ratio of the amount of oxygen atoms (oxygen atomic ratio) relative to total amount of silicon atoms, oxygen atoms and carbon atoms, and a carbon distribution curve showing the relationship between the L and ratio of the amount of carbon atoms (carbon atomic ratio) relative to total amount of silicon atoms, oxygen atoms and carbon atoms, abundance be high in the order of (oxygen atomic ratio), (silicon atomic ratio), (carbon atomic ratio) (atomic ratio of O>Si>C) within at least 90% film thickness region of the first barrier layer (upper limit: 100%). When the requirement (i) is not satisfied, the gas barrier film to be obtained might have an insufficient gas barrier property or bending property. Herein, in the carbon distribution curve, the relationship among (oxygen atomic ratio), (silicon atomic ratio), (carbon atomic ratio) is more preferably satisfied within at least 90% film thickness region of the first barrier layer (upper limit: 1000), and more preferably satisfied within at least 93% film thickness region of the first barrier layer (upper limit: 100%). Herein, the expression “at least 90% film thickness region of the first barrier layer” does not require continuity in the first barrier layer, and it is sufficient to satisfy the relationship just within a region of at least 90%.

Furthermore, in the first barrier layer, it is preferable that (ii) the carbon distribution curve have at least two extreme values. The first barrier layer more preferably has at least three extreme values, and even more preferably at least four extreme values in the carbon distribution curve. However, it may have five or more extreme values. When the extreme value is 1 or less in the carbon distribution curve, the gas barrier property may become insufficient when the gas barrier film is bent. Meanwhile, the upper limit of the extreme value of the carbon distribution curve is, although not particularly limited, preferably 30 or less, and more preferably 25 or less, for example. However, as the number of extreme values is affected also by the film thickness of a first barrier layer, it cannot be defined uniformly.

Herein, when there are at least three extreme values, the absolute value of a difference of the distance (L) from a surface of the first barrier layer in film thickness direction of the first barrier layer between at one extreme value in the carbon distribution curve and at the extreme value adjacent to the aforementioned extreme value (hereinbelow, also simply referred to as “distance between extreme values”), is preferably 200 nm or less, more preferably 100 nm or less, and particularly preferably 75 nm or less in any cases. With such distance between extreme values, a region having high carbon atomic ratio (local maximum value) is present at suitable period in the first barrier layer, and thus suitable bending property is given to the first barrier and an occurrence of cracks can be effectively suppressed and prevented at the time of bending a gas barrier film. Meanwhile, the term “extreme value” described herein means the local maximum value or the local minimum value of the atomic ratio of an atom relative to the distance (L) from a surface of the first barrier layer in film thickness direction of the first barrier layer. Furthermore, the “local maximum value” described herein means a point at which the atomic ratio value of an atom (oxygen, silicon, or carbon) changes from increase to decrease when the distance from a surface of the first barrier layer is changed, and the atomic ratio value of an element at a position which results from a change of the distance from a surface of the first barrier layer in film thickness direction of the first barrier layer within a range of 4 to 20 nm from the aforementioned point is decreased by 3 at % or more relative to the atomic ratio value of the element of the aforementioned point. In other words, it is sufficient that, when a change is made within a region of from 4 to 20 nm, the atomic ratio value of an element is decreased by 3 at % or more in any range. Similarly, the “local minimum value” described herein means a point at which the atomic ratio value of an atom (oxygen, silicon, or carbon) changes from decrease to increase when the distance from a surface of the first barrier layer is changed, and the atomic ratio value of an element at a position which results from a change of the distance from a surface of the first barrier layer in film thickness direction of the first barrier layer within a range of 4 to 20 nm from the aforementioned point is increased by 3 at % or more relative to the atomic ratio value of the element of the aforementioned point. In other words, it is sufficient that, when a change is made within a region of from 4 to 20 nm, the atomic ratio value of an element is increased by 3 at % or more in any range. Herein, for a case of having at least three extreme values, the lower limit of the distance between extreme values is not particularly limited as the effect of suppressing/preventing an occurrence of cracks during bending of a gas barrier film increases as the distance between extreme values decreases. However, considering the bending property of the first barrier layer, effect of suppressing/preventing an occurrence of cracks, thermal expansion or the like, it is preferably 10 nm or more, and more preferably 30 nm or more.

Furthermore, in the first barrier layer, it is preferable that (iii) the absolute value of a difference between the maximum value and the minimum value of the carbon atomic ratio in the carbon distribution curve (hereinbelow, also simply referred to as “difference of Cₘₐₓ−Cₘᵢₙ”) be 3 at % or more. When the absolute value is less than 3 at %, the gas barrier property may become insufficient when the gas barrier film to be obtained is bent. The difference of Cₘₐₓ−Cₘᵢₙ is preferably 5 at % or more, more preferably 7 at % or more, and particularly preferably 10 at % or more. By having the aforementioned difference of Cₘₐₓ−Cₘᵢₙ, the gas barrier property can be further improved. Meanwhile, as described herein, the “maximum value” means the atomic ratio of each element representing the maximum in distribution curve of each element, indicating the largest value among the local maximum values. Similarly, the “minimum value” described herein means the atomic ratio of each element representing the lowest in distribution curve of each element, indicating the smallest value among the local minimum values. Herein, the upper limit of the difference of Cₘₐₓ−Cₘᵢₙ is, although not particularly limited, preferably 50 at % or less and more preferably 40 at % or less considering the effect of suppressing/preventing an occurrence of cracks during bending of a gas barrier film.

In the present invention, the oxygen distribution curve of the first barrier layer preferably has at least one extreme value, more preferably at least two extreme values, and even more preferably at least three extreme values. When the oxygen distribution curve has at least one extreme value, the obtained gas barrier film after bending shows more improved gas barrier property compared to a gas barrier film having no extreme value. Meanwhile, the upper limit of the extreme value of the oxygen distribution curve is, although not particularly limited, preferably 20 or less, and more preferably 10 or less. The number of extreme values in oxygen distribution curve cannot be uniformly defined because it is partially affected by film thickness of a first barrier film. Furthermore, when there are at least three extreme values, the absolute value of a difference of the distance from a surface of the first barrier layer in film thickness direction of the first barrier layer between at one extreme value in the oxygen distribution curve and the distance from a surface of the first barrier layer in film thickness direction of the first barrier layer and at the extreme value adjacent to the aforementioned extreme value, is preferably 200 nm or less, and more preferably 100 nm or less. With such distance between extreme values, an occurrence of cracks can be effectively suppressed and prevented at the time of bending a gas barrier film. Herein, for a case of having at least three extreme values, the lower limit of the distance between extreme values is, although not particularly limited, preferably 10 nm or more, and more preferably 30 nm or more considering the effect of suppressing/preventing an occurrence of cracks at the time of bending a gas barrier film, thermal expansion or the like.

Furthermore, in the first barrier layer, the absolute value of a difference between the maximum value and the minimum value of the oxygen atomic ratio in the oxygen distribution curve (hereinbelow, also simply referred to as “difference of Oₘₐₓ−Oₘᵢₙ”) is preferably 3 at % or more, more preferably 6 at % or more, and even more preferably 7 at % or more. When the absolute value is 3 at % or more, the gas barrier property of the gas barrier film to be obtained is improved more when the gas barrier film is bent. Herein, the upper limit of the difference of Oₘₐᵣ−Oₘᵢₙ is, although not particularly limited, preferably 50 at % or less and more preferably 40 at % or less considering the effect of suppressing/preventing an occurrence of cracks during bending of a gas barrier film.

Furthermore, in the first barrier layer, the absolute value of a difference between the maximum value and the minimum value of the silicon atomic ratio in the silicon distribution curve (hereinbelow, also simply referred to as “difference of Siₘₐₓ−Siₘᵢₙ”) is preferably 10 at % or less, more preferably 7 at % or less, and even more preferably 3 at % or less. When the absolute value is 10 at % or less, the gas barrier property of the gas barrier film to be obtained is improved more. Herein, the lower limit of the difference of Siₘₐₓ−Siₘᵢₙ is not particularly limited because the effect of suppressing/preventing an occurrence of cracks during bending of a gas barrier film increase as the difference of Siₘₐₓ−Siₘᵢₙ decreases. However, considering the gas barrier property or the like, it is preferably 1 at % or more and more preferably 2 at % or more.

It is preferable that the total amount of carbon and oxygen atoms in film thickness direction of a first barrier layer be almost constant. Accordingly, the first barrier layer exhibits suitable bending property so that an occurrence of cracks is effectively suppressed and prevented at the time of bending a gas barrier film. More specifically, with regard to an oxygen carbon distribution curve showing the relationship between the distance (L) from a surface of the first barrier layer in film thickness direction of the first barrier layer and ratio of the total amount of oxygen and carbon atoms (oxygen and carbon atomic ratio) relative to total amount of silicon atoms, oxygen atoms and carbon atoms, the absolute value of a difference between the maximum value and the minimum value of the oxygen and carbon atomic ratio in the oxygen carbon distribution curve (hereinbelow, also simply referred to as “difference of OCₘₐₓ−OCₘᵢₙ”) is preferably less than 5 at %, more preferably less than 4 at %, and even more preferably less than 3 at %. When the absolute value is less than 5 at %, the gas barrier property of the gas barrier film to be obtained is improved more. Meanwhile, the lower limit of the difference of OCₘₐₓ−OCₘᵢₙ is 0 at % because the smaller difference of OCₘₐₓ−OCₘᵢₙ is preferred more. However, it is sufficiently 0.1 at % or more.

The aforementioned silicon distribution curve, oxygen distribution curve, carbon distribution curve, and oxygen carbon distribution curve can be established by a so-called XPS depth profile measurement in which sequential surface composition analysis is performed by having both the X ray photoelectron spectroscopy (XPS) and ion sputtering of rare gas such as argon while exposing the inside of a sample. The distribution curve obtained by such XPS depth profile measurement can be established by having atomic ratio of each atom (unit: at %) at vertical axis and etching time (sputtering time) at horizontal axis. Meanwhile, with regard to a distribution curve of an element in which etching time is plotted at horizontal axis, the etching time is roughly related to the distance (L) from a surface of the first barrier layer in film thickness direction of the first barrier layer. Thus, as a “distance from a surface of the first barrier layer in film thickness direction of the first barrier layer”, the distance from a surface of the first barrier layer which is calculated in view of the relationship between the etching speed and etching time employed for XPS depth profile measurement can be used. Meanwhile, the silicon distribution curve, oxygen distribution curve, carbon distribution curve, and oxygen carbon distribution curve can be established under the following measurement conditions.

(Measurement Conditions)

Ion species for etching: Argon (Ar⁺)

Etching speed (values converted in terms of thermally oxidized SiO₂ film): 0.05 nm/sec

Etching space (values converted in terms of SiO₂): 10 nm

X ray photoelectron spectroscopy apparatus: type “VG Theta Probe” manufactured by Thermo Fisher Scientific

X ray for irradiation: Single crystal spectrophotometric AlKα

Spot and size of X ray: oval with a size of 800×400 μm.

Film thickness (dry film thickness) of the first barrier layer formed by a plasma CVD method is not particularly limited as long as the requirements (i) to (iii) are satisfied. For example, the film thickness per layer of the first barrier layer is preferably 20 to 3000 nm, more preferably 50 to 2500 nm, and even more preferably 100 to 1000 nm. With such film thickness, the gas barrier film can exhibit an excellent gas barrier property and the effect of suppressing/preventing an occurrence of cracks during bending. Meanwhile, when the first barrier layer formed by a plasma CVD method consists of two or more layers, each first barrier layer preferably has the aforementioned film thickness.

In the present invention, from the viewpoint of forming a first barrier layer which is uniform over entire film surface and has an excellent gas barrier property, it is preferable that the first barrier layer be substantially even in film surface direction (direction parallel to a surface of a first barrier layer). As described herein, the expression “the first barrier layer is substantially even in film surface direction” means that, when the aforementioned oxygen distribution curve, carbon distribution curve, and oxygen carbon distribution curve are established by XPS depth profile for measurement point of at any two points on a film surface of a first barrier layer, the number of extreme value in the carbon distribution curve is same for those any two measurement points so that the absolute value of a difference between the maximum value and the minimum value of the carbon atomic ratio in each carbon distribution curve is identical to each other or has a difference of 5 at % or less.

Furthermore, in the present invention, it is preferable that the carbon distribution curve be substantially continuous. As described herein, the expression “the carbon distribution curve is substantially continuous” means that the carbon distribution curve includes no region in which carbon atomic ratio discontinuously changes. Specifically, with regard to a relationship between the distance (x, unit; nm) from a surface of a first barrier layer in film thickness direction of at least one layer in the first barrier layer and carbon atomic ratio (C, unit; at %), which is calculated from etching speed and etching time, the conditions represented by the following Mathematical Formula 1 are satisfied.

[Mathematical Formula 1]

(dC/dx)≦0.5 Mathematical Formula 1

In the gas barrier film according to the present invention, the first barrier layer satisfying all the requirements (i) to (iii) may have only one layer or two or more layers. Furthermore, when there are two or more layers of a first barrier layer, material of plural first barrier layers may be either same or different from each other.

In the silicon distribution curve, oxygen distribution curve, and carbon distribution curve, when the silicon atomic ratio, oxygen atomic ratio, and carbon atomic ratio satisfy the condition represented by (i) above in at least 90% film thickness region of the first barrier layer, the atomic content ratio of the silicon atom relative to the total amount of silicon atom, oxygen atom, and carbon atom in the first barrier layer is preferably 20 to 45 at %, and more preferably 25 to 40 at %. Furthermore, the atomic content ratio of the oxygen atom relative to the total amount of silicon atom, oxygen atom, and carbon atom in the first barrier layer is preferably 45 to 75 at %, and more preferably 50 to 70 at %. Furthermore, the atomic content ratio of the carbon atom relative to the total amount of silicon atom, oxygen atom, and carbon atom in the first barrier layer is preferably 0.5 to 25 at %, and more preferably 1 to 20 at %.

According to the present invention, the method for forming a first barrier layer is not particularly limited, and a method of a related art can be similarly used or used after suitable modification. The first barrier layer is preferably formed by a chemical vapor phase growing method (CVD method), in particular, plasma chemical vapor phase growing method (plasma CVD, PECVD (plasma-enhanced chemical vapor deposition), hereinbelow, also simply referred to as a “plasma CVD method”). In particular, it is more preferably formed by a plasma CVD method in which a substrate is disposed on top of a pair of film forming rollers and plasma is generated by having discharge between the pair of film forming rollers.

Hereinbelow, descriptions are given for a method of forming a first barrier layer on a substrate by a plasma CVD method in which a substrate is disposed on top of a pair of film forming rollers and plasma is generated by having discharge between the pair of film forming rollers.

<<Method for Forming First Barrier Layer by Plasma CVD Method>>

As a method for forming the first barrier layer according to the present invention on a surface of a substrate, it is preferable to employ a plasma CVD method from the viewpoint of a gas barrier property. Meanwhile, the plasma CVD method can be a plasma CVD method of a Penning discharge plasma mode.

When plasma is generated by a plasma CVD method, it is preferable that plasma discharge be generated within a space between plural film forming rollers. It is more preferable that one pair of film forming rollers be used, a substrate be disposed for each of the pair of film forming rollers, and plasma be generated by having discharge between the pair of film forming rollers. By using one pair of film forming rollers, disposing a substrate on top of each of the pair of film forming rollers, and having plasma discharge between the pair of film forming rollers, not only the a surface part of a substrate which is present on one film forming roller can be formed into a film but also a surface of a substrate which is present on other film forming roller can be simultaneously formed into a film, and thus a thin film can be produced efficiently. In addition, compared to a conventional plasma CVD method which does not use a roller, the film forming speed can be doubled and also a film with almost the same structure can be formed. Accordingly, it is possible to increase at least two times the extreme values in a carbon distribution curve so that a layer satisfying the aforementioned requirements (i) to (iii) can be efficiently formed.

Furthermore, for having discharge between a pair of film forming rollers as described above, it is preferable that the polarity of the pair of film forming rollers be reversed alternately. Furthermore, the film forming gas used for such plasma CVD method preferably contains an organic silicon compound and oxygen. Content of the oxygen in the film forming gas is preferably less than a theoretical oxygen amount which is required for complete oxidation of the entire amount of the organic silicon compound in the film forming gas. Furthermore, with regard to the gas barrier film of the present invention, the first barrier layer is preferably a layer formed by a continuous film forming process.

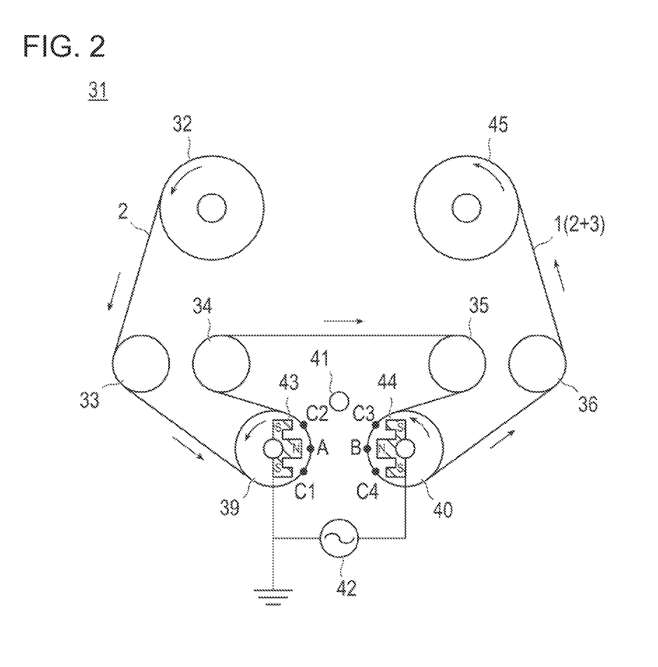

Furthermore, with regard to the gas barrier film of the present invention, the first barrier layer is preferably formed by a roll-to-roll process on a surface of the substrate from the viewpoint of productivity. Furthermore, the apparatus which can be used for producing the first barrier layer by plasma CVD method is, although not particularly limited, preferably an apparatus having at least one pair of film forming rollers and a plasma source and having a constitution allowing discharge between the pair of film forming rollers. For example, when the manufacturing apparatus illustrated in FIG. 2 is used, it is also possible to have manufacturing according to roll-to-roll process while using a plasma CVD method.

Hereinbelow, more detailed descriptions are given for a method for forming a first barrier layer by a plasma CVD method in which a substrate is disposed on a pair of film forming rollers and plasma is generated by having discharge between the pair of film forming rollers while referring to FIG. 2. Meanwhile, FIG. 2 is a schematic drawing illustrating an example of a manufacturing apparatus that can be preferably used for manufacturing a first barrier layer by the present manufacturing method. Furthermore, in the following descriptions and drawings, same symbols are given for the same or similar elements and redundant descriptions are not provided.

The manufacturing apparatus 31 illustrated in FIG. 2 includes the feed roller 32, the conveying rollers 33, 34, 35, 36, the film forming rollers 39, 40, the gas supplying pipe 41, the power source 42 for generating plasma, the device 43, 44 for generating magnetic field which is installed inside the film forming rollers 39 and 40, and the take-up roller 45. Further, in this manufacturing apparatus, at least the film forming rollers 39, 40, the gas supplying pipe 41, the power source 42 for generating plasma, and the devices 43, 44 for generating magnetic field are disposed inside a vacuum chamber which is not illustrated. Furthermore, in this manufacturing apparatus 31, the aforementioned non-illustrated vacuum chamber is connected to a vacuum pump such that inside pressure of the vacuum chamber can be suitably adjusted by the vacuum pump.

In this manufacturing apparatus, each film forming roller is connected to the power source 42 for generating plasma such that a pair of film forming rollers (the film forming roller 39 and the film forming roller 40) can function as a pair of counter electrodes. As such, according this manufacturing apparatus 31, discharge can be generated in a space between the film forming roller 39 and the film forming roller 40 by supplying electric power with an aid of the power source 42 for generating plasma. Accordingly, plasma can be generated in a space between the film forming roller 39 and the film forming roller 40. Meanwhile, when the film forming roller 39 and the film forming roller 40 are also used as an electrode, their material or design can be suitably modified such that they can be also used as an electrode. Furthermore, in this manufacturing apparatus, a pair of film forming rollers (the film forming rollers 39 and 40) is preferably disposed such that the center axis is almost parallel on the same plane. By disposing a pair of film forming rollers (the film forming rollers 39 and 40) in such manner, the film forming speed can be doubled and also a film with almost the same structure can be formed. Accordingly, it is possible to increase at least two times the extreme values in a carbon distribution curve. Furthermore, according to this manufacturing apparatus, it is possible to form the first barrier layer 3 on a surface of the substrate 2 by a CVD method, and also a first barrier layer component can be additionally deposited on a surface of the substrate 2 on the film forming roller 40 while a first barrier layer component is deposited on a surface of the substrate 2 on the film forming roller 39. As such, the first barrier layer can be efficiently formed on a surface of the substrate 2.

Within the film forming roller 39 and the film forming roller 40, the device 43 and 44 for generating magnetic field, which are fixed so as not to rotate according to rotation of a film forming roller, are installed, respectively.

With regard to the devices 43 and 44 for generating magnetic field, which are installed on the film forming roller 39 and the film forming roller 40, respectively, the magnetic poles are preferably disposed such that there are no magnetic force lines between the device 43 for generating magnetic field which is installed on the film forming roller 39 at one side and the device 44 for generating magnetic field which is installed on the film forming roller 40 at the other side and each of the devices 43, 44 for generating magnetic field forms almost closed magnetic circuit. Disposing the devices 43, 44 for generating magnetic field is favorable in that forming of a magnetic field with expanded magnetic force lines can be promoted near the surface opposite to the film forming rollers 39, 40 and plasma can be easily bound to that expanded region, and thus the film forming efficiency can be enhanced.

It is also preferable that the devices 43, 44 for generating magnetic field, which are installed for the film forming roller 39 and the film forming roller 40, respectively, be provided with a magnetic pole of a race track shape which is extended long in roller axis direction, and with respect to the device 43 for generating magnetic field on one side and the device 44 for generating magnetic field on the other side, the magnetic poles are arranged such that facing magnetic poles have the same polarity. By installing the devices 43, 44 for generating magnetic field, magnetic field with race track shape can be easily formed near roller surface that is in contact with the opposite space (discharge area) along the length direction of a roller axis without having magnetic force lines present on the apparatus for generating magnetic field on the opposite roller side, and plasma can be concentrated to the magnetic field for each of the devices 43, 44 for generating magnetic field, and thus it is excellent in that the first barrier layer 3 as a vapor deposition film can be efficiently formed by using wide substrate 2 wound in the roller width direction.

As for the film forming roller 39 and the film forming roller 40, a known roller can be suitably used. From the viewpoint of forming more efficiently a thin film, a roller having same diameter is preferably used as the film forming rollers 39 and 40. Furthermore, from the viewpoint of discharge conditions, chamber space, or the like, the diameter of the film forming rollers 39 and 40 is preferably within a range of 300 to 1000 mmφ, in particularly within a range of 300 to 700 mmφ. When the diameter of a film forming roller is 300 mmφ or more, space for plasma discharge is not reduced so that there is no deterioration in productivity and application of entire heat from plasma discharge to the substrate 2 can be avoided to reduce damages on the substrate 2, and therefore desirable. Meanwhile, when the diameter of a film forming roller is 1000 mmφ or less, a practical value can be maintained in terms of apparatus design including uniformity of a plasma discharge space, and therefore desirable.

In the manufacturing apparatus 31, the substrate 2 is disposed on a pair of film forming rollers (the film forming roller 39 and the film forming roller 40) such that each surface of the substrate 2 can face each other. By disposing the substrate 2 in such manner, when plasma is generated by performing discharge in a counter space between the film forming roller 39 and the film forming roller 40, each surface of the substrate 2 present between a pair of film forming rollers can be simultaneously prepared as a film. Specifically, with this manufacturing apparatus, a first barrier component can be deposited on a surface of the substrate 2 on the film forming roller 39 and also a first barrier component can be deposited on a surface of the substrate 2 on the film forming roller 40 by a plasma CVD method, and thus the first barrier layer can be efficiently formed on a surface of the substrate 2.

A known roller can be suitably used as the feed roller 32 and the conveying rollers 33, 34, 35, 36 that are used for the manufacturing apparatus. Furthermore, as for the take-up roller 45, anyone capable of taking up the gas barrier film 1 having the first barrier layer 3 formed on the substrate 2 can be used. A known roller can be suitably used without being particularly limited.

Furthermore, as the gas supplying pipe 41 and a vacuum pump, any one capable of supplying or discharging a raw material gas or the like at a predetermined rate can be suitably used.

Furthermore, the gas supplying pipe 41 as a gas supplying means is preferably installed on one side of a counter space (discharge area; film forming zone) between the film forming roller 39 and the film forming roller 40, and the vacuum pump (not illustrated) as a vacuum discharge means is preferably installed on the other side of a counter space. By disposing the gas supplying pipe 41 as a gas supplying means and a vacuum pump as a vacuum discharge means, the film forming gas can be efficiently supplied to a counter space between the film forming roller 39 and the film forming roller 40, and it is thus excellent in that the film forming efficiency can be enhanced.

Furthermore, a power source of a known plasma generator can be used as the power source 42 for generating plasma. The power source 42 for generating plasma supplies electric power to the film forming roller 39 and the film forming roller 40 that are connected to the power source and enables use of them as a counter electrode for discharge. As the power source 42 for generating plasma, use of a source enabling alternate reverse of polarity of a pair of the film forming rollers (alternating power source) is preferable in that more efficient operation of plasma CVD can be achieved.

Furthermore, as the power source 42 for generating plasma, a power source allowing application power of 100 W to 10 kW and alternating current frequency of 50 Hz to 500 kHz is more preferable in that more efficient operation of plasma CVD can be achieved. Furthermore, as the devices 43, 44 for generating magnetic field, a known magnetic field generator can be suitably used. Furthermore, as the substrate 2, a substrate on which the first barrier layer 3 is formed in advance can be used in addition to the substrate used in the present invention. By using as the substrate 2 a substrate on which the first barrier layer 3 is formed in advance, it is also possible to increase the film thickness of the first barrier layer 3.

By using the manufacturing apparatus 31 illustrated in FIG. 2 and adjusting type of a raw material gas, power of an electrode drum of a plasma generator, pressure in a vacuum chamber, the diameter of a film forming roller, and conveyance speed of a film (substrate), the first barrier layer of the present invention can be manufactured. Specifically, by using the manufacturing apparatus 31 illustrated in FIG. 2 and having discharge between a pair of film forming rollers (the film forming rollers 39 and 40) while supplying a film forming gas (raw material gas or the like) to a vacuum chamber, the film forming gas (raw material gas or the like) is decomposed by plasma and the first barrier layer 3 is formed on a surface of the substrate 2 on the film forming roller 39 and on a surface of the substrate 2 on the film forming roller 40 by a plasma CVD method. At that time, magnetic field of a race track shape is formed near the roller surface in contact with a counter space (discharge area) along the length direction of a roller axis of the film forming rollers 39, 40, and plasma is concentrated to the magnetic field. Accordingly, when the substrate 2 passes point A of the film forming roller 39 and point B of the film forming roller 40 in FIG. 2, the local maximum value of a carbon distribution curve is formed in a first barrier layer. On the other hand, when the substrate 2 passes points C1 and C2 of the film forming roller 39 and points C3 and C4 of the film forming roller 40 in FIG. 2, the local minimum value of a carbon distribution curve is formed in a first barrier layer. As such, five extreme values are generally formed for two film forming rollers. Furthermore, the distance between extreme values in the first barrier layer (absolute value of a difference of the distance (L) from a surface of the first barrier layer in film thickness direction of the first barrier layer between at one extreme value in the carbon distribution curve and the distance (L) from a surface of the first barrier layer in film thickness direction of the first barrier layer and at the extreme value adjacent to the aforementioned extreme value) can be controlled based on revolution speed of the film forming rollers 39, 40 (conveyance speed of a substrate). Furthermore, during such film forming, the substrate 2 is conveyed by the feed roller 32 or the film forming roller 39 so that the first barrier layer 3 is formed on a surface of the substrate 2 by a continuous film forming process of roll-to-roll type.

As for the film forming gas (raw material gas or the like) which is supplied from the gas supplying pipe 41 to the counter space, raw material gas, reactive gas, carrier gas, or discharge gas can be used either singly or as a mixture of two or more types. The raw material gas in the filming forming gas which is used for forming the first barrier layer 3 can be suitably selected and used depending on the material of the first barrier layer 3 to be formed. Examples of the raw material gas which can be used include an organic silicon compound containing silicon or organic compound gas containing carbon. Examples of the organic silicon compound include hexamethyldisiloxane (HMDSO), hexamethyldisilane (HMDS), 1,1,3,3-tetra methyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetra methoxysilane (TMOS), tetra ethoxysilane (TEOS), phenyltrimethoxysilane, methyltriethoxysilane, and octamethylcyclotetra siloxane. Among these organic silicon compounds, from the viewpoint of the handling property of a compound and gas barrier property of a first barrier layer to be obtained, hexamethyldisiloxane and 1,1,3,3-tetra methyldisiloxane are preferable. The organic silicon compound can be used either singly or in combination of two or more types. Examples of the organic compound gas containing carbon include methane, ethane, ethylene, and acetylene. With regard to the organic silicon compound and organic compound gas, a suitable raw material gas is selected depending on type of the first barrier layer 3.

Furthermore, reactive gas can be also used as film forming gas in addition to the aforementioned raw material gas. As for the reactive gas, gas capable of reacting with the raw material gas to yield an inorganic compound such as oxides and nitrides can be suitably selected and used. As for the reactive gas for forming oxides, oxygen and ozone can be used, for example. Furthermore, as for the reactive gas for forming nitrides, nitrogen and ammonia can be used, for example. The reactive gas can be used either singly or in combination of two or more types. When it is necessary to form oxynitride, for example, it is possible that reactive gas for forming oxide and reactive gas for forming nitride can be used in combination.

As for the film forming gas, if necessary, carrier gas may be used for supplying the raw material gas to a vacuum chamber. Furthermore, as the film forming gas, discharge gas may be used, if necessary, to generate plasma discharge. As for the carrier gas and discharge gas, known gas can be suitably used, and rare gas such as helium, argon, neon, or xenon; and hydrogen can be used.

Regarding the ratio between the raw material gas and reactive gas when the film forming gas contains raw material gas and reactive gas, ratio of the reactive gas is preferably not exceedingly higher than the ratio of reactive gas which is theoretically required to have a complete reaction between the raw material gas and reactive gas. Not having exceedingly higher ratio of the reactive gas is favorable in that an excellent barrier property or bending resistance can be obtained from the first barrier layer 3 to be formed. Furthermore, when the film forming gas contains the organic silicon compound and oxygen, it is preferably to have an amount which is equal to or less than the theoretical oxygen amount which is required to have complete oxidation of the entire organic silicon compound contained in the film forming gas.

Hereinbelow, more detailed descriptions are given with regard to the preferred ratio of raw material gas and reactive gas in the film forming gas in view of an example in which the film forming gas containing hexamethyldisiloxane (organic silicon compound, HMDSO, (CH₃)₆Si₂O) as raw material gas and oxygen (O₂) as reactive gas is used for manufacturing a silicon-oxygen based thin film.

For a case in which a silicon-oxygen based thin film is manufactured by a reaction, which is based on plasma CVD, of film forming gas containing hexamethyldisiloxane (HMDSO, (CH₃)₆Si₂O) as raw material gas and oxygen (O₂) as reactive gas, a reaction represented by the following Reaction Formula 1 is caused by the film forming gas to yield silicon dioxide.

[Chem. 1]

(CH₃)₆Si₂O+12O₂→6CO₂+9H₂O+2SiO₂ Reaction Formula 1

In the reaction, the amount of oxygen required for complete oxidation of 1 mol of hexamethyldisiloxane is 12 moles. For such reasons, when a complete oxidation is allowed to occur while having oxygen at 12 moles or more relative to 1 mol of hexamethyldisiloxane in the film forming gas, an even silicon dioxide film is formed (carbon distribution curve does not exist), and thus a first barrier layer satisfying all the requirements (i) to (iii) cannot be formed. Thus, when a first barrier layer is formed in the present invention, it is preferable that the oxygen amount relative to 1 mol of hexamethyldisiloxane be less than 12 moles as a stoichiometric amount such that the reaction of the above Reaction Formula 1 cannot progress completely. Meanwhile, for the actual reaction occurring in a plasma CVD chamber, a complete reaction cannot be practically obtained even when the molar amount (flow amount) of oxygen as reactive gas is times the molar amount (flow amount) of hexamethyldisiloxane as a raw material, because hexamethyldisiloxane as a raw material and oxygen as reactive gas are supplied from a gas supply part to a film forming region to form a film. Thus, it is believed that the complete reaction can be obtained only after supplying the oxygen in an amount which is excessively higher than the stoichiometric ratio (for example, to obtain silicon oxide by complete oxidation based on CVD, there is a case in which molar amount (flow amount) of oxygen is 20 times or higher than the molar amount (flow amount) of hexamethyldisiloxane as a raw material). For such reasons, the molar amount (flow amount) of oxygen relative to the molar amount (flow amount) of hexamethyldisiloxane as a raw material is preferably 12 times or less, which is a stoichiometric ratio (more preferably, it is 10 times or less). By containing hexamethyldisiloxane and oxygen at this ratio, carbon atoms or hydrogen atoms in incompletely oxidized hexamethyldisiloxane are introduced to a first barrier layer, and thus a first barrier satisfying all the requirements (i) to (iii) can be formed. Accordingly, the gas barrier film obtained therefrom can exhibit an excellent gas barrier property and bending resistance. Meanwhile, from the viewpoint of use for a flexible substrate for a device which requires transparency such as an organic EL element and a solar cell, the lower limit of the molar amount (flow amount) of oxygen with respect to the molar amount (flow amount) of hexamethyldisiloxane in the film forming gas is preferably higher than 0.1 times the molar amount (flow amount) of hexamethyldisiloxane. More preferably, it is higher than 0.5 times.

Furthermore, the pressure (vacuum level) inside a vacuum chamber can be suitably adjusted depending on type of a raw material gas or the like. However, it is preferably in a range of from 0.5 Pa to 50 Pa.

Furthermore, to have discharge between the film forming roller 39 and the film forming roller 40 according to the plasma CVD method, electric power applied to an electrode drum, which is connected to the power source 42 for generating plasma (in this embodiment, it is installed at the film forming rollers 39 and 40) is preferably in a range of from 0.1 to 10 kW, although it cannot be uniformly defined as it can be suitably defined by the type of a raw material gas or pressure in a vacuum chamber or the like. When the application power is 100 W or more, an occurrence of particles can be sufficiently suppressed. On the other hand, when it is 10 kW or less, heat generated during film forming can be suppressed so that an increase in substrate surface temperature during film forming can be suppressed. Thus, it is excellent in that the substrate is not lost against heat and an occurrence of wrinkles can be prevented during film forming.

The conveyance speed (line speed) of the substrate 2 can be suitably adjusted according to the type of a raw material gas or pressure in a vacuum chamber. However, it is preferably in a range of from 0.25 to 100 m/min, and more preferably in a range of from 0.5 to 20 m/min. When the line speed is 0.25 m/min or higher, an occurrence of substrate wrinkles which is caused by heat can be prevented effectively. On the other hand, when it 100 m/min or less, it is excellent in that sufficient film thickness of a first barrier layer can be ensured without deteriorating the productivity.

As described above, the more preferred mode of the present embodiment is characterized in that film forming of a first barrier layer according to the present invention is performed by plasma CVD method in which a plasma CVD apparatus (roll-to-roll process) having counter roll electrodes illustrated in FIG. 2 is used. That is because, when mass production is performed by using a plasma CVD apparatus (roll-to-roll process) having counter roll electrodes, a first barrier layer having excellent flexibility (bending property) and also the mechanical strength, in particular, durability during roll-to-roll conveyance, and barrier performance can be efficiently manufactured. Such manufacturing apparatus is also excellent in that a gas barrier film required to have durability against temperature change, which is used for a solar cell or an electronic compartment, can be easily produced in a large amount at low cost.

<Coating Method>

The first barrier layer according to the present invention may be also formed by a forming method based on converting treatment of a coating film which is formed by coating a liquid containing an inorganic compound, and preferably a liquid containing silicon compound (coating method). Hereinbelow, descriptions are given for an example in which the inorganic compound is a silicon compound, but the inorganic compound is not limited to a silicon compound.

(Silicon Compound)

The silicon compound is not particularly limited if it allows preparation of a coating liquid containing silicon compound.

Specific examples thereof include perhydropolysilazane, organo polysilazane, silsesquioxane, tetra methylsilane, trimethylmethoxysilane, dimethyldimethoxysilane, methyltrimethoxysilane, trimethylethoxysilane, dimethyldiethoxysilane, methyltriethoxysilane, tetra methoxysilane, tetra methoxysilane, hexamethyldisiloxane, hexamethyldisilazane, 1,1-dimethyl-1-silacyclobutane, trimethylvinylsilane, methoxydimethylvinylsilane, trimethoxyvinylsilane, ethyltrimethoxysilane, dimethyldivinylsilane, dimethylethoxyethynylsilane, diacetoxydimethylsilane, dimethoxymethyl-3,3,3-trifluoropropylsilane, 3,3,3-trifluoropropyltrimethoxysilane, aryltrimethoxysilane, ethoxydimethylvinylsilane, arylaminotrimethoxysilane, N-methyl-N-trimethylsilylacetamide, 3-aminopropyltrimethoxysilane, methyltrivinylsilane, diacetoxymethylvinylsilane, methyltriacetoxysilane, aryloxydimethylvinylsilane, diethylvinylsilane, butyltrimethoxysilane, 3-aminopropyldimethylethoxysilane, tetra vinylsilane, triacetoxyvinylsilane, tetra acetoxysilane, 3-trifluoroacetoxypropyltrimethoxysilane, diaryldimethoxysilane, butyldimethoxyvinylsilane, trimethyl-3-vinylthiopropylsilane, phenyltrimethylsilane, dimethoxymethylphenylsilane, phenyltrimethoxysilane, 3-acryloxypropyldimethoxymethylsilane, 3-acryloxypropyltrimethoxysilane, dimethylisopentyloxyvinylsilane, 2-aryloxyethylthiomethoxytrimethylsilane, 3-glycidoxypropyltrimethoxysilane, 3-arylaminopropyltrimethoxysilane, hexyltrimethoxysilane, heptadecafluorodecyltrimethoxysilane, dimethylethoxyphenylsilane, benzoyloxytrimethylsilane, 3-methacryloxypropyldimethoxymethylsilane, 3-methacryloxypropyltrimethoxysilane, 3-isocyanatepropyltriethoxysilane, dimethylethoxy-3-glycidoxypropylsilane, dibutoxydimethylsilane, 3-butylaminopropyltrimethylsilane, 3-dimethylaminopropyldiethoxymethylsilane, 2-(2-aminoethylthioethyl)triethoxysilane, bis(butylamino)dimethylsilane, divinylmethylphenylsilane, diacetoxymethylphenylsilane, dimethyl-p-tolylvinylsilane, p-styryltrimethoxysilane, diethylmethylphenylsilane, benzyldimethylethoxysilane, diethoxymethylphenylsilane, decylmethyldimethoxysilane, diethoxy-3-glycidoxypropylmethylsilane, octyloxytrimethylsilane, phenyltrivinylsilane, tetra aryloxysilane, dodecyltrimethylsilane, diarylmethylphenylsilane, diphenylmethylvinylsilane, diphenylethoxymethylsilane, diacetoxydiphenylsilane, dibenzyldimethylsilane, diaryldiphenylsilane, octadecyltrimethylsilane, methyloctadecyldimethylsilane, docosylmethyldimethylsilane, 1,3-divinyl-1,1,3,3-tetra methyldisiloxane, 1,3-divinyl-1,1,3,3-tetra methyldisilazane, 1,4-bis(dimethylvinylsilyl)benzene, 1,3-bis(3-acetoxypropyl)tetra methyldisiloxane, 1,3,5-trimethyl-1,3,5-trivinylcyclotrisiloxane, 1,3,5-tris(3,3,3-trifluoropropyl)-1,3,5-trimethylcyclotrisiloxane, octamethylcyclotetra siloxane, 1,3,5,7-tetra ethoxy-1,3,5,7-tetra methylcyclotetra siloxane, and decamethylcyclopentasiloxane. The silicon compound can be used either singly or in combination of two or more types.

Examples of the silsesquioxane include Q8 series manufactured by Mayaterials and hydrogenated silsesquioxane which does not contain an organic group.

Among them, from the viewpoint of having a film forming property, less defects such as crack, and less residual organic matters, polysilazane such as perhydropolysilazane and organo polysilazane; and polysiloxane such as silsesquioxane are preferable. From the viewpoint of having a high gas barrier property and maintaining barrier performance during bending or under high temperature and high moisture conditions, polysilazane is more preferable, and perhydropolysilazane is particularly preferable.

Polysilazane indicates a polymer having a silicon-nitrogen bond and it is a ceramic precursor inorganic polymer such as SiO₂, Si₃N₄, or an intermediate solid solution of SiOₓN_{y} containing a bond such as Si—N, Si—H, and N—H.

Specifically, preferred structure of polysilazane is as described below.

[Chem. 2]

—[Si(R₁)(R₂)—N(R₃)]ₙ— General Formula (I)

In the above General Formula (I), R₁, R₂ and R₃ each independently represent a hydrogen atom, a substituted or unsubstituted alkyl group, an aryl group, a vinyl group or a (trialkoxysilyl)alkyl group. R₁, R₂ and R₃ may be each the same or different from each other. Examples of the alkyl group described herein include a linear, branched, or cyclic alkyl group having 1 to 8 carbon atoms. More specific examples thereof include a methyl group, an ethyl group, a n-propyl group, an isopropyl group, an-butyl group, an isobutyl group, a sec-butyl group, a tert-butyl group, a n-pentyl group, an isopentyl group, a neopentyl group, a n-hexyl group, a n-heptyl group, a n-octyl group, a 2-ethylhexyl group, a cyclopropyl group, a cyclopentyl group, and a cyclohexyl group. Examples of the aryl group include an aryl group having 6 to 30 carbon atoms. More specific examples thereof include a non-fused hydrocarbon group such as a phenyl group, a biphenyl group, or a terphenyl group; and a fused polycyclic hydrocarbon group such as a pentalenyl group, an indenyl group, a naphthyl group, an azulenyl group, a heptalenyl group, a biphenylenyl group, a fluorenyl group, an acenaphthylenyl group, a pleiadenyl group, an acenaphthenyl group, a phenalenyl group, a phenanthryl group, an anthryl group, a fluoranethenyl group, an acephenanthrylenyl group, an aceanthrylenyl group, a triphenylenyl group, a pyrenyl group, a chrysenyl group, and a naphthacenyl group. Examples of the (trialkoxysilyl)alkyl group include an alkyl group having 1 to 8 carbon atoms in which a silyl group substituted with an alkoxy group having 1 to 8 carbon atoms is included. More specific examples thereof include a 3-(triethoxysilyl)propyl group and a 3-(trimethoxysilyl)propyl group. The substituent group which may be present depending on a case on the aforementioned R₁ to R₃ is not particularly limited, and examples thereof include an alkyl group, a halogen atom, a hydroxy group (—OH), a mercapto group (—SH), a cyano group (—CN), a sulfo group (—SO₃H), a carboxy group (—COOH), and a nitro group (—NO₂). Meanwhile, the substituent group which may be present depending on a case is not the same as the R₁ to R₃ to be substituted. For example, when R₁ to R₃ are an alkyl group, it is not further substituted with an alkyl group. Among them, R₁, R₂ and R₃ are preferably a hydrogen atom, a methyl group, an ethyl group, a propyl group, an isopropyl group, a butyl group, an isobutyl group, a tert-butyl group, a phenyl group, a vinyl group, a 3-(triethoxysilyl)propyl group, or a 3-(trimethoxysilylpropyl) group.

It is also preferable to set the n in General Formula (I), which is an integer, is determined such that the polysilazane having the structure represented by the above General Formula (I) has a number average molecular weight of 150 to 150,000 g/mol.

One preferred mode of the compound having the structure represented by the above General Formula (I) is perhydropolysilazane in which all of R₁, R₂ and R₃ are a hydrogen atom.

Alternatively, polysilazane has a structure represented by the following General Formula (II).

[Chem. 3]

—[Si(R_{1′})(R_{2′})—N(R_{3′})]_{n′}—[Si(R_{4′})(R_{5′})—N(R_{6′})]ₚ— General Formula (II)

In the above General Formula (II), R_{1′}, R_{2′}, R_{3′}, R_{4′}, R_{5′} and R_{6′} each independently represent a hydrogen atom, a substituted or unsubstituted alkyl group, an aryl group, a vinyl group or a (trialkoxysilyl)alkyl group. R_{1′}, R_{2′}, R_{3′}, R_{4′}, R_{5′} and R_{6′} may be each the same or different from each other. Because the substituted or unsubstituted alkyl group, aryl group, vinyl group or (trialkoxysilyl)alkyl group are as defined in the above for General Formula (I), no further descriptions are given therefor.

It is also preferable to set the n′ and p in General Formula (II), which are an integer, are determined such that the polysilazane having the structure represented by the above General Formula (II) has a number average molecular weight of 150 to 150,000 g/mol. Meanwhile, n′ and p may be the same or different from each other.

Among the polysilazanes of General Formula (II), a compound in which R_{1′}, R_{3′} and R_{6′} each represent a hydrogen atom and R_{2′}, R_{4′} and R_{5′} each represent a methyl group; a compound in which R_{1′}, R_{3′} and R_{6′} each represent a hydrogen atom, R_{2′}, R_{4′} each represent a methyl group, and R_{5′} represents a vinyl group; a compound in which R_{1′}, R_{3′}, R_{4′} and R_{6′} each represent a hydrogen atom and R_{2′} and R_{5′} each represent a methyl group are preferable.

Alternatively, polysilazane has a structure represented by the following General Formula (III).

[Chem. 4]

—[Si(R_{1″})(R_{2″})—N(R_{8″})]_{n″}—[Si(R_{4″})(R_{5″})—N(R_{6″})]_{n″}—[Si(R_{7″})(R_{8″})—N(R_{9″})]ₙ— General Formula (III)

In the above General Formula (III), R_{1″}, R_{2″}, R_{3″}, R_{4″}, R_{5″}, R_{6″}, R_{7″}, R_{8″} and R_{9″} each independently represent a hydrogen atom, a substituted or unsubstituted alkyl group, an aryl group, a vinyl group or a (trialkoxysilyl)alkyl group. R_{1″}, R_{2″}, R_{3″}, R_{4″}, R_{5″}, R_{6″}, R_{7″}, R_{8″} and R_{9″} may be each the same or different from each other. Because the substituted or unsubstituted alkyl group, aryl group, vinyl group or (trialkoxysilyl)alkyl group are as defined in the above for General Formula (I), no further descriptions are given therefor.

It is also preferable to set the n″, p″, and q in General Formula (III), which are an integer, are determined such that the polysilazane having the structure represented by the above General Formula (III) has a number average molecular weight of 150 to 150,000 g/mol. Meanwhile, n″, p″, and q may be the same or different from each other.

Among the polysilazanes of General Formula (III), a compound in which R_{1″}, R_{3″} and R_{6″} each represent a hydrogen atom, R_{2″}, R_{4″}, R_{5″} and R_{8″} each represent a methyl group, R_{9″} represents a (triethoxysilyl)propyl group and R_{7″} represents an alkyl group or a hydrogen atom is preferable.

Meanwhile, when organo polysilazane in which a part of the hydrogen atoms bonded to Si is substituted with an alkyl group or the like, adhesiveness to a substrate as a base is improved by having an alkyl group such as a methyl group, and a ceramic film which is hard and brittle can be provided with toughness by polysilazane. Thus, there is an advantage that an occurrence of cracks is suppressed even when (average) film thickness is increased. As such, perhydropolysilazane and organo polysilazane can be suitably selected depending on use, and they can also be used as a mixture.

The perhydropolysilazane is believed to have a structure in which a linear chain structure and a ring structure having 6- and 8-membered ring as a main ring are present. The molecular weight is about 600 to 2,000 (polystyrene conversion value) in terms of a number average molecular weight (Mn). It is a material of liquid or solid, and the state differs depending on the molecular weight.

Polysilazane is commercially available in a solution state in which it is dissolved in an organic solvent. The commercially available product itself can be used as a coating liquid containing for forming the first barrier layer. Examples of the commercially available polysilazane solution include AQUAMICA (registered trademark) NN120-10, NN120-20, NAX120-20, NN110, NN310, NN320, NL110A, NL120A, NL120-20, NL150A, NP110, NP140, SP140 and the like, that are manufactured by AZ Electronic Materials.

Another examples of polysilazane that can be used in the present invention include polysilazane which is, not limited as follows, ceramized at low temperature such as silicon alkoxide added polysilazane, being produced by reacting silicon alkoxide with polysilazane (JP 5-238827 A); glycidol added polysilazane, being produced by reacting glycidol (JP 6-122852 A); alcohol added polysilazane, being produced by reacting alcohol (JP 6-240208 A); metal carboxylic acid added polysilazane, being produced by reacting metal carboxylate (JP 6-299118 A); acetyl acetonate complex added polysilazane, being produced by reacting acetyl acetonate complex containing a metal (JP 6-306329 A); and metal fine particle added polysilazane, being produced by adding metal fine particles (JP 7-196986 A).

In the case of using polysilazane, the content of polysilazane in the first barrier layer before conversion treatment can be 100% by weight when the whole amount of the first barrier layer is 100% by weight. Further, for a case in which the first barrier layer contains those other than polysilazane, the content of polysilazane in the layer is preferably 10% by weight to 99% by weight, more preferably 40% by weight to 95% by weight, and particularly preferably 70% by weight to 95% by weight.

The forming method based on coating of the first barrier layer is not particularly limited, and a known method can be employed. However, preferred is a method in which a coating liquid for forming a first barrier layer containing a silicon compound in an organic solvent, and if necessary, a catalyst is coated by a known wet type coating method, the solvent is removed by evaporation, and a conversion treatment is performed.

(Coating Liquid for Forming First Barrier Layer)

A solvent for preparing a coating liquid for forming a first barrier layer is not particularly limited, as long as it can dissolve a silicon compound. However, an organic solvent not including water and a reactive group which easily react with a silicon compound (for example, a hydroxyl group or an amine group) and being inert to the silicon compound is preferable. Aprotic organic solvent is more preferable. Specific examples of the solvent include an aprotic solvent; for example, hydrocarbon solvent such as an aliphatic hydrocarbon, an alicyclic hydrocarbon or an aromatic hydrocarbon such as pentane, hexane, cyclohexane, toluene, xylene, solvesso, or terpene; a halogenated hydrocarbons such as methylene chloride, or trichloroethane; esters such as ethyl acetate and butyl acetate; ketones such as acetone and methyl ethyl ketone; ethers such as aliphatic ether and alicyclic ether such as dibutyl ether, dioxane, or tetra hydrofuran, for example, tetra hydrofuran, dibutyl ether, mono- and polyalkylene glycol dialkyl ether (diglymes). The solvent is selected depending on purpose such as ability of dissolving a silicon compound or evaporation rate of a solvent. It may be used either singly or as a mixture of two or more types.

Although the silicon compound concentration in the coating liquid for forming a first barrier layer is not particularly limited and varies in accordance with the film thickness of the layer or the pot life of the coating liquid, it is preferably 1 to 80% by weight, more preferably 5 to 50% by weight, and particularly preferably 10 to 40% by weight

In order to promote the conversion, a catalyst is preferably contained in a coating liquid for forming the first barrier layer. As a catalyst which can be applied for the present invention, a basic catalyst is preferable. In particular, an amine catalyst such as N,N-diethylethanolamine, N,N-dimethylethanolamine, triethanolamine, triethylamine, 3-morpholino propylamine, N,N,N′,N′-tetra methyl-1,3-diaminopropane, or N,N,N′,N′-tetra methyl-1,6-diaminohexanoic acid, a metal catalyst including a Pt compound such as Pt acetyl acetonate, a Pd compound such as Pd propionate, and a Rh compound such as Rh acetylacetonate, and an N-heterocyclic compound can be exemplified. Among them, it is preferable to use an amine catalyst. While taking the silicon compound as a reference, a concentration of the catalyst to be added is usually within a range of 0.1 to 10% by weight preferably, within a range of 0.5 to 7% by weight more preferably. By having an addition amount of the catalyst within the range, having an excessive forming amount of silanol, a decrease in film density, and an increase in film defects that are caused by a rapid progress of the reaction can be avoided.

If necessary, the following additives can be used in a coating liquid for forming the first barrier layer. Examples include cellulose ethers, cellulose esters; for example, ethylcellulose, nitrocellulose, cellulose acetate, and cellulose acetobutylate, natural resins; for example, rubbers and rosin resins, synthetic resins; for example, polymerized resins, condensed resins; for example, aminoplast, in particular, urea resin, melamine formaldehyde resin, alkyd resin, acrylic resin, polyester or modified polyester, epoxide, polyisocyanate, or blocked polyisocyanate, and polysiloxane.

As described in JP 2005-231039 A, a sol-gel method can be used for forming a first barrier layer. A coating liquid used for forming a first barrier layer by a sol gel method preferably contains a silicon compound and at least one of a polyvinyl alcohol resin and ethylene•vinyl alcohol copolymer. The coating liquid also preferably contains a catalyst for sol-gel method, acid, water, and an organic solvent. According to a sol-gel method, a first barrier layer is obtained by polycondensation using such coating liquid. As for the silicon compound, an alkoxide represented by the general formula R^{A}₀Si(OR^{B})ₚ is preferably used. In the formula, R^{A} and R^{B} each independently represent an alkyl group having 1 to 20 carbon atoms, O represents an integer of 0 or more, and p represents an integer of 1 or more. Specific examples of the alkoxysilane which can be used include tetra methoxysilane (Si(OCH₃)₄), tetra ethoxysilane (Si(OC₂H₅)₄), tetra propoxysilane (Si(OC₃H₇)₄), and tetra butoxysilane (Si(OC₄H₉)₄). When a polyvinyl alcohol resin and an ethylene•vinyl alcohol copolymer are used in combination in a coating liquid, blending ratio of each is, in terms of weight ratio, as follows; polyvinyl alcohol resin:ethylene•vinyl alcohol copolymer=10:0.05 to 10:6. Furthermore, content of the polyvinyl alcohol resin and/or ethylene•vinyl alcohol copolymer in a coating liquid is preferably in the range of 5 to 500 parts by weight, and more preferably 20 to 200 parts by weight relative to 100 parts by weight of a total amount of the silicon compound. As for the polyvinyl alcohol resin, those obtained by saponification of polyvinyl acetates can be generally used. With regard to the polyvinyl alcohol resin, it may be any one of partially saponified polyvinyl alcohol resin in which several tens of percentage of acetic acid group are present, a fully saponified polyvinyl alcohol resin in which no acetic acid group is present, and a modified polyvinyl alcohol resin with modified OH group. Specific examples of the polyvinyl alcohol resin which can be used include KURARAY POVAL (registered trademark) manufactured by KURARAY CO., Ltd. and Gohsenol (registered trademark) manufactured by The Nippon Synthetic Chemical Industry Co., Ltd. Further, in the present invention, a saponification product of a copolymer between ethylene and vinyl acetate, that is, a product obtained by saponification of an ethylene-vinyl acetate random copolymer can be used as an ethylene•vinyl alcohol copolymer. Specifically, a partially saponified polyvinyl alcohol resin in which several tens of molar percentage of acetic acid group are present, a partially saponified polyvinyl alcohol resin in which only several molar percentage of acetic acid group are present, and a fully saponified polyvinyl alcohol resin having no acetic acid group are included. Further, although it is not particularly limited, saponification degree preferred from the viewpoint of a gas barrier property is preferably 80 mol % or more, more preferably 90 mol % or more, and even more preferably 95 mol % or more. Furthermore, with regard to the content of a repeating unit derived from ethylene in the ethylene•vinyl alcohol copolymer (also referred to as “ethylene content” hereinbelow), those having 0 to 50 mol % in general, and preferably 20 to 45 mol % are preferably used. Specific examples of the ethylene•vinyl alcohol copolymer which can be used include EVAL (registered trademark) EP-F101 (ethylene content; 32 mol %) manufactured by KURARAY CO., Ltd. and Soarnol (registered trademark) D2908 (ethylene content; 29 mol %) manufactured by The Nippon Synthetic Chemical Industry Co., Ltd. As a catalyst for a sol-gel method, mainly a polycondensation catalyst, tertiary amine which is substantially insoluble in water but soluble in an organic solvent is used. Specifically, N,N-dimethylbenzylamine, tripropylamine, tributylamine, tripentylamine, or the like can be used, for example. Further, examples of the acid include those that are used as the catalyst for sol-gel method, or mainly a catalyst for hydrolysis such as alkoxide or silane coupling agent. Examples of the acid which can be used include mineral acid such as sulfuric acid, hydrochloric acid, or nitric acid, and organic acid such as acetic acid and tartaric acid. Furthermore, it is preferable that, in a coating liquid, water be contained at ratio of preferably 0.1 to 100 mol, and more preferably 0.8 to 2 mol relative to 1 mol of the total molar amount of alkoxide.

Examples of the organic solvent which is used for a coating liquid for a sol-gel method include methyl alcohol, ethyl alcohol, n-propyl alcohol, isopropyl alcohol, and n-butanol. Furthermore, as an ethylene•vinyl alcohol copolymer solubilized in a solvent, commercially available ones such as Soarnol (registered trademark, manufactured by The Nippon Synthetic Chemical Industry Co., Ltd.) can be used. Furthermore, for example, a silane coupling agent can be also added to a coating liquid for a sol-gel method.

(Method for Coating a Coating Liquid for Forming First Barrier Layer)

As for the method of applying a coating liquid for forming a first barrier layer, any suitable known wet coating method may be used. Specific examples thereof include a spin coating method, a roll coating method, a flow coating method, an inkjet method, a spray coating method, a printing method, a dip coating method, a cast film forming method, a bar coating method, and Gravure printing method.

The coating thickness can be suitably set depending on the purpose. For example, the coating thickness per one layer of the first barrier layer is preferably 10 nm to 10 μm, more preferably 15 nm to 1 μm, and even more preferably 20 to 500 nm in terms of thickness after drying. When the film thickness is 10 nm or more, a sufficient barrier property can be obtained. On the other hand, when it is 10 μm or less, a stable coating property can be obtained during layer forming and also high light transmission can be achieved.

It is preferable to dry a coating film after coating a coating liquid. According to drying of a coating film, an organic solvent contained in the coating film can be removed. At that time, the organic solvent contained in the coating film can be removed entirely or some of the solvent may remain. Even for a case in which some of the solvent remain, a preferred first barrier layer can be obtained. Meanwhile, the remaining solvent can be removed later.

Drying temperature of a coating film varies depending on a substrate for application. However, it is preferably 50 to 200° C. For example, in a case in which a polyethylene terephthalate substrate with a glass transition temperature (Tg) of 70° C. is used as a substrate, the drying temperature is preferably set at 150° C. or lower considering deformation of a substrate caused by heat or the like. The temperature can be set by using a hot plate, an oven, a furnace or the like. The drying time is preferably set to short time and it is preferably to be set to 30 minutes or shorter when the drying temperature is 150° C. Furthermore, the drying atmosphere can be any one condition including air atmosphere, nitrogen atmosphere, argon atmosphere, vacuum atmosphere, and reduced pressure atmosphere with controlled oxygen concentration.

The coating film obtained by coating a coating liquid for forming a first barrier layer may be subjected to a step for removing moisture either before the conversion treatment or during the conversion treatment. A method for removing moisture is preferably in the form of removing moisture while maintaining a low-humidity environment. Since humidity in the low-humidity environment varies with temperature, the preferred form of the relation between the temperature and the humidity is indicated by defining dew-point temperature. The dew-point temperature is preferably 4° C. or lower (temperature of 25° C./humidity of 25%), more preferably −5° C. (temperature of 25° C./humidity of 10%) or lower, and keeping time is preferably appropriately set depending on the film thickness of a first barrier layer. It is preferable that the dew point temperature be −5° C. or lower and the keeping time is 1 minute or longer on the condition of the film thickness of the first barrier layer of 1.0 μm or less. Incidentally, the lower limit of the dew-point temperature is not particularly limited, but is generally −50° C. or higher, and preferably −40° C. or higher. Performing a step for removing moisture either before the conversion treatment or during the conversion treatment is preferable from the viewpoint of promoting a dehydration reaction of a first barrier layer which is converted into silanol.

<Modification Treatment of First Barrier Layer Formed by Coating Method>

In the present invention, a conversion treatment of a first barrier layer formed by a coating method indicates a conversion reaction of a silicon compound into silicon oxide, silicon oxynitride, or the like. Specifically, it indicates a treatment of forming an inorganic thin film to the level at which the gas barrier film of the present invention as a whole can contribute to exhibiting the gas barrier property.

A known method can be suitably selected and applied for the conversion reaction of a silicon compound into silicon oxide, silicon oxynitride, or the like. Specific examples of the conversion treatment include a plasma treatment, an ultraviolet ray irradiation treatment, and a heating treatment. Meanwhile, because conversion by a heating treatment requires high temperature of 450° C. or more for forming a silicon oxide film or a silicon oxynitride layer based on a substitution reaction of a silicon compound, it is difficult to be applied for a flexible substrate such as plastics. For such reasons, the heating treatment is preferably performed in combination of other conversion treatment.

As such, from the viewpoint of application to a plastic substrate, a conversion reaction based on a plasma treatment or an ultraviolet ray irradiation treatment allowing a conversion treatment at lower temperature is preferred as a conversion treatment.

(Plasma Treatment)

In the present invention, a known method can be used for a plasma treatment which can be used as a conversion treatment. However, an atmospheric pressure plasma treatment can be mentioned as a preferred example. The atmospheric pressure plasma CVD method by which a plasma CVD treatment is performed near atmospheric pressure has not only high productivity by not requiring reduced pressure but also has high film forming rate due to high plasma density compared to a plasma CVD method under vacuum. Furthermore, compared to conditions for general CVD method, the average free step for gas is very short at high pressure conditions of atmospheric condition, and thus a very even film is obtained.

In the case of an atmospheric pressure plasma treatment, nitrogen gas and/or gas containing an atom in the 18th group of the long-period periodic table, specifically helium, neon, argon, krypton, xenon, radon or the like is used as discharge gas. Among them, nitrogen, helium and argon are preferably used. In particular, nitrogen is preferred in that the cost is low.

(Heating Treatment)

By performing a heating treatment of a coating film containing a silicon compound in combination with other conversion treatment, preferably an excimer irradiation treatment described below, the conversion treatment can be performed efficiently.

Furthermore, when a layer is formed by using a sol-gel method, it is preferably to use a heating treatment. With regard to the heating conditions, by performing heating and drying at a temperature of preferably 50 to 300° C., and more preferably 70 to 200° C. for preferably 0.005 to 60 minutes and more preferably 0.01 to 10 minutes, the first barrier layer can be formed according to progress of condensation.

Examples of the heating treatment include a method of heating a coating film with heat conduction by bringing a substrate into contact with a heat generator such as a heat block, a method of heating the atmosphere by an external heater with resistance wire or the like, a method using light in an infrared region such as an IR heater, and the like. However, the heat treatment is not particularly limited. Further, a method capable of maintaining smoothness of a coating film containing a silicon compound may be appropriately selected.

It is preferable to appropriately adjust a coating film temperature to be in a range of 50 to 250° C. during the heating treatment. It is more preferably in a range of 50 to 120° C.

Moreover, the heating time is preferably in a range of 1 second to 10 hours, and more preferably in a range of 10 seconds to 1 hour.

(Ultraviolet Ray Irradiation Treatment)

A treatment by ultraviolet ray irradiation is preferred as one method for a conversion treatment. Ozone or active oxygen atom produced by ultraviolet ray (same meaning as ultraviolet light) has a high oxidizing ability, and thus it allows forming of a silicon oxide film or a silicon oxynitride film which has high density and insulating property at low temperature.

As the substrate is heated and O₂ and H₂O which contribute to ceramization (silica conversion), or an ultraviolet ray absorbing agent, polysilazane itself are excited and activated by ultraviolet ray irradiation, the polysilazane is excited, ceramization of polysilazane is promoted, and a more dense first barrier layer is obtained therefrom. The ultraviolet ray irradiation is effective as long as it is performed at any point after forming a coating film.

For the ultraviolet ray irradiation treatment, any commercially available ultraviolet ray generator can be used.

Meanwhile, the ultraviolet ray described herein generally means an electromagnetic wave having a wavelength of 10 to 400 nm. For the ultraviolet ray irradiation treatment other than the vacuum ultraviolet ray (10 to 200 nm) treatment, ultraviolet ray of 210 to 375 nm is preferably used.

As for the ultraviolet ray irradiation, it is preferable that irradiation intensity and irradiation time be set in a range in which the substrate supporting the first barrier layer is not damaged.

For a case in which a plastic film is used as a substrate, for example, irradiation can be performed for 0.1 second to 10 minutes by using a lamp of 2 kW (80 W/cm×25 cm) and setting a distance between a substrate and a lamp for ultraviolet ray irradiation such that the intensity on a substrate surface is 20 to 300 mW/cm², and preferably 50 to 200 mW/cm².

Generally, in the case of a plastic film or the like, the characteristics of the substrate are deteriorated such that the substrate is deformed or the strength thereof is degraded when the temperature of the substrate during the ultraviolet ray irradiation treatment becomes 150° C. or higher. However, in the case of a film of polyimide or the like, which has a high heat resistance, a conversion treatment can be performed at a higher temperature. Therefore, the temperature of the substrate during ultraviolet ray irradiation does not have a general upper limit and can be appropriately set according to the type of the substrate by a person skilled in the art. The ultraviolet ray irradiation atmosphere is not particularly limited and may be performed in the air.

Examples of the unit for generating an ultraviolet ray include, but are not limited to, a metal halide lamp, a high-pressure mercury lamp, low-pressure mercury lamp, a xenon arc lamp, a carbon arc lamp, an excimer lamp (single wavelength of 172 nm, 222 nm or 308 nm; manufactured by, for example, USHIO Inc. or M. D. Com. Inc.) and an ultraviolet ray laser. When the first barrier layer is irradiated with an ultraviolet ray generated, from the viewpoint of improving efficiency and achieving uniform irradiation, it is preferable to apply the ultraviolet ray from the generation source to the first barrier layer after reflecting the ultraviolet ray by a reflection plate.

Ultraviolet irradiation is applicable either to batch treatment or to continuous treatment, and a selection can be appropriately made according to the shape of a substrate that is used. For example, in the case of batch treatment, a laminate having the first barrier layer on the surface can be treated in an ultraviolet furnace including an ultraviolet generation source as described above. The ultraviolet furnace itself is generally known, and for example an ultraviolet furnace manufactured by EYE GRAPHICS Co., Ltd. can be used. When the laminate having the first barrier layer on the surface is in the form of a long film, it can be ceramized by continuously applying an ultraviolet ray in a drying zone including an ultraviolet generation source as described above while conveying the laminate. The required time for ultraviolet irradiation depends on the composition and concentration of the substrate used and the first barrier layer, but is generally 0.1 second to 10 minutes, preferably 0.5 second to 3 minutes.

(Vacuum Ultraviolet Ray Irradiation Treatment: Excimer Irradiation Treatment)

In the present invention, the most preferred conversion treatment method is a treatment by vacuum ultraviolet irradiation (excimer irradiation treatment). The treatment by vacuum ultraviolet irradiation is a method of forming a silicon oxide film at a relatively low temperature (about 200° C. or lower) by allowing an oxidization reaction by active oxygen or ozone to proceed while directly cutting the bond of atoms by the action of only photons, which is called a light quantum process, using light energy of 100 to 200 nm, which is greater than an interatomic bonding force within a polysilazane compound, preferably using energy of light having a wavelength of 100 to 180 nm. Meanwhile, when an excimer irradiation treatment is performed, it is preferable to have a heating treatment in combination as described above, and detailed conditions for the heating treatment are as described above.

A radiation source of the present invention can be any one which emits light with wavelength of from 100 to 180 nm, and it is preferably is an excimer radiator (for example, a Xe excimer lamp) having the maximum radiation at about 172 nm, a low-pressure mercury vapor lamp having an emission line at about 185 nm, medium-pressure and high-pressure mercury vapor lamps having a wavelength component of 230 nm or less, and an excimer lamp having the maximum radiation at about 222 nm.

Among them, a Xe excimer lamp is excellent in efficiency of light emission since an ultraviolet ray having a short wavelength of 172 nm is radiated at a single wavelength. Since this light has a high oxygen absorption coefficient, the light enables a high concentration of a radical oxygen atomic species or ozone to be generated with a very small amount of oxygen.

Further, the energy of light having a short wavelength of 172 nm is known to have a high capacity which dissociates the bond of organic material. Modification of a polysilazane coating film can be realized in a short time by the high energy of this active oxygen or ozone and ultraviolet radiation.

The excimer lamp can be made to illuminate by input of a low power because of having high light generation efficiency. Further, the excimer lamp does not emit light with a long wavelength which becomes a factor for increasing temperature due to light but emits light in an ultraviolet range, that is, applies irradiation of energy with a short wavelength. Therefore, the excimer lamp has a characteristic of capable of suppressing increase in the surface temperature of an article to be irradiated. Accordingly, the excimer lamp is suitable for a flexible film material such as PET which is considered to be easily affected by heat.

Oxygen is required for the reaction by ultraviolet ray irradiation. However, since the vacuum ultraviolet ray has absorption by oxygen, efficiency may be easily lowered during vacuum ultraviolet ray irradiation. Therefore, vacuum ultraviolet ray irradiation is preferably carried out in a state in which oxygen concentration and water vapor concentration are as low as possible. The oxygen concentration during the vacuum ultraviolet ray irradiation is preferably 10 to 20,000 ppm by volume, and more preferably 50 to 10,000 ppm by volume. Further, the water vapor concentration during the conversion process is preferably in a range of 1,000 to 4,000 ppm by volume.

A gas satisfying the irradiation atmosphere used for vacuum ultraviolet ray irradiation is preferably dry inert gas, and in particular, is preferably dry nitrogen gas from the viewpoint of cost. The adjustment of oxygen concentration can be achieved by changing flow amount ratio after measuring flow amount of oxygen gas and inert gas that are introduced to an irradiation cabin.

In the vacuum ultraviolet ray irradiation process, illuminance of the vacuum ultraviolet ray with which the polysilazane coating film is irradiated, on the coating film surface, is preferably 1 mW/cm² to 10 W/cm², more preferably 30 mW/cm² to 200 mW/cm², and even more preferably 50 mW/cm² to 160 mW/cm². When the illuminance is lower than 1 mW/cm², the conversion efficiency may be greatly lowered. On the other hand, when it is higher than 10 W/cm², an ablation may occur on a coating film or a substrate may suffer from damage.

An irradiation energy amount (irradiation amount) of the vacuum ultraviolet rayon the surface of the coating film is preferably 10 to 10,000 mJ/cm², more preferably 100 to 8,000 mJ/cm², and even more preferably 200 to 6,000 mJ/cm². When it is lower than 10 mJ/cm², the conversion may become insufficient. On the other hand, when it is higher than 10,000 mJ/cm², an occurrence of cracks caused by excessive conversion or substrate deformation caused by heat may occur.

Furthermore, the vacuum ultraviolet ray used for the conversion may be generated by plasma which has been formed with gas containing at least one of CO, CO₂ and CH₄ (hereinbelow, also referred to as carbon-containing gas). Furthermore, although the carbon-containing gas may be used singly, it is preferably used as mixture gas in which rare gas or H₂ is contained as a main gas and a small amount of carbon-containing gas is added. Examples of a method for generation plasma include capacitively-coupled plasma.

Next, for a preferred embodiment in which the silicon compound is perhydropolysilazane, descriptions are given for a reaction mechanism which is believed to be involved with generation of silicon oxynitride, and further silicon oxide from perhydropolysilazane during a vacuum ultraviolet irradiation process.

(I) Dehydrogenation and Forming of Si—N Bond Accompanied Therewith

It is believed that Si—H bond or N—H bond in perhydropolysilazane is relatively easily broken by excitation or the like by vacuum ultraviolet ray irradiation and binds again as Si—N under an inert atmosphere (non-bonding arm of Si may be also formed). That is, it is cured as SiN_{y} composition without oxidation, and thus breakage of a polymer main chain does not occur. Breakage of Si—H bond or N—H bond is promoted by presence of a catalyst or by heating. Broken H is released as H₂ to an outside of the film.

(II) Forming of Si—O—Si Bond by Hydrolysis and Dehydration Condensation

According to hydrolysis of Si—N bond in perhydropolysilazane by water and breakage of a polymer main chain, Si—OH is formed. According to dehydration condensation of two Si—OH, curing is obtained with forming of Si—O—Si bond. Although the reaction occurs also in air, it is believed that, during vacuum ultraviolet ray irradiation under an inert atmosphere, water vapor generated as an out gas from a substrate caused by heat of irradiation is believed to a main source of moisture. When moisture is present in an excessive amount, Si—OH not consumed by dehydration condensation remains, and thus a curing film with low gas barrier property that is represented by the composition of SiO_{2.1} to SiO_{2.3} is yielded.

(III) Direct Oxygenation and Forming of Si—O—Si Bond Caused by Singlet Oxygen

When a suitable amount of oxygen is present in an atmosphere during vacuum ultraviolet ray irradiation, singlet oxygen having significantly high oxidizing ability is formed. H and N in perhydropolysilazane are replaced with O to form a Si—O—Si bond, and thus causing curing. It is also considered that recombination of bonds may also occur according to breakage of a polymer main chain.

(IV) Oxidation Accompanied with Si—N Bond Breakage Caused by Vacuum Ultraviolet Ray Irradiation and Excitation

It is believed that, since energy of vacuum ultraviolet ray is greater than the bond energy of Si—N in perhydropolysilazane, Si—N bond is broken and oxidized to generate Si—O—Si bond or Si—O—N bond when an oxygen source such as oxygen, ozone, and water is present in the neighborhood. It is believed that recombination of bonds may also occur according to breakage of a polymer main chain.

Adjusting the composition of silicon oxynitride in a layer which is obtained by performing vacuum ultraviolet ray irradiation on a layer containing polysilazane can be carried out by controlling an oxidation state by combining suitably the oxidation mechanisms (I) to (IV) described above.

Herein, in the case of polysilazane as a preferred silicon compound, breakage of Si—H, N—H bond and forming of Si—O bond occur according to silica conversion (conversion treatment), yielding conversion into ceramics such as silica. By an IR measurement, degree of the conversion can be semi quantitatively evaluated in terms of SiO/SiN ratio based on Formula (1) defined below.

[Mathematical Formula 2]

SiO/SiN ratio=(SiO absorbance after conversion)/(SiN absorbance after conversion) Formula (1)

As described herein, the SiO absorbance is calculated from the absorption of about 1160 cm⁻¹ and the SiN absorbance is calculated from the absorption of about 840 cm⁻¹. A larger SiO/SiN ratio indicates that conversion into ceramic close to the silica composition has advanced.

As described herein, the SiO/SiN ratio as an index of conversion degree into ceramic is preferably 0.3 or more, and more preferably 0.5 or more. When it is less than 0.3, the desired gas barrier property may not be obtained. Further, as a measurement method of a silica conversion rate (x in SiOₓ), for example, the XPS method can be used for measurement.

The film composition of the first barrier layer can be measured by measuring an atom composition ratio using an XPS surface analyzer. In addition, the film composition thereof can be also measured by cutting the first barrier layer and measuring the atom composition ratio of the cut surface thereof by the XPS surface analyzer.

Further, the film density of a first barrier layer can be suitably set depending on the object. For example, the film density of a first barrier layer is preferably within a range of from 1.5 to 2.6 g/cm³. When it is not within this range, deterioration of a barrier property due to decreased film density or film oxidation deterioration caused by moisture may occur.

The first barrier layer may be a single layer or has a laminated structure in which two or more layers are present.

For a case in which the first barrier layer has a laminated structure in which two or more layers are present, each first barrier layer may have the same or difference composition. Furthermore, for a case in which the first barrier layer has a laminated structure in which two or more layers are present, the first barrier layer may consist of only a layer formed by a vacuum film forming method, may consist of only a layer formed by a coating method, or may be a combination of a layer formed by a vacuum film forming method and a layer formed by a coating method.

Furthermore, from the viewpoint of stress relaxation property or absorbing ultraviolet ray used for forming a second barrier described below, the first barrier layer preferably contains a nitrogen atom or a carbon atom. By containing those atoms, it is possible to have a stress relaxation property or an ultraviolet ray absorbing property. It is also preferable in that an effect of improving gas barrier property is obtained as adhesiveness between a first barrier layer and a second barrier layer is enhanced.

Chemical composition of the first barrier layer can be controlled based on type and amount of a silicon compound used for forming the first barrier layer, conditions for converting a layer containing a silicon compound, or the like.

[Second Barrier Layer]

A second barrier layer according to the present invention which is formed on top of a first barrier layer contains at least silicon atoms and oxygen atoms, and an abundance ratio of oxygen atoms to silicon atoms (O/Si) is 1.4 to 2.2 and an abundance ratio of nitrogen atoms to silicon atoms (N/Si) is 0 to 0.4.

As described herein, the expression “an abundance ratio of oxygen atoms to silicon atoms (O/Si) is 1.4 to 2.2” means that, with regard to the points at any depth of a second barrier layer for which measurement is performed by an apparatus and a method described above, there is no part which exhibits an O/Si value of less than 1.4 or more than 2.2. Similarly, the expression “an abundance ratio of nitrogen atoms to silicon atoms (N/Si) is 0 to 0.4” means that, with regard to the points at any depth of a second barrier layer for which measurement is performed by an apparatus and a method described above, there is no part which exhibits a N/Si value of more than 0.4.

When the abundance ratio of oxygen atoms to silicon atoms (O/Si) is 1.4 or more in the second barrier layer, the second barrier is not likely to react with moisture under high temperature and high moisture conditions, and thus a film having improved barrier property can be easily formed. On the other hand, when it is 2.2 or less, a silanol group (Si—OH) is reduced in the molecule and it is difficult to have a route for moisture transfer, and thus a sufficient barrier property is obtained. The O/Si is preferably 1.5 to 2.1, and more preferably 1.7 to 2.0.

When the abundance ratio of nitrogen atoms to silicon atoms (N/Si) is 0.4 or less in the second barrier layer, the second barrier is not likely to react with moisture under high temperature and high moisture conditions, and thus a film having improved barrier property can be easily formed. The N/Si is preferably 0 to 0.3, and more preferably 0 to 0.2.

The O/Si and N/Si can be controlled by an addition amount of an addition compound as stated below, such as water, an alcohol compound, metal alkoxide compound or the like, irradiation energy amount of vacuum ultraviolet ray, irradiation temperature or the like.

The O/Si and N/Si can be measured according to the following method. Specifically, composition profile of a second barrier layer can be obtained by combining an Ar sputter etching apparatus and X ray photoelectron spectroscopic method (XPS). Furthermore, the profile distribution in depth direction can be calculated by membrane processing using FIB (Focused Ion Beam) processing apparatus and obtaining an actual film thickness by TEM (Transmission type electron microscope), and matching it to the result obtained by XPS.

In the present invention, an apparatus and a method described below were used.

(Sputtering Conditions)

Ion species: Ar ion

Acceleration voltage: 1 kV

(Measurement Conditions for X Ray Photoelectron Spectroscopy)

Apparatus: ESCALAB-200R manufactured by VG Scientifix Co., Ltd.

X ray anode material: Mg

Output: 600 W (acceleration voltage: 15 kV, emission current: 40 mA)

Meanwhile, the measurement resolution was 0.5 nm and each atomic ratio is plotted for each sampling point according to the resolution.

(FIB Processing)

Apparatus: SMI2050 manufactured by SII

Processing ion: (Ga 30 kV)

(TEM Measurement)

Apparatus: JEM2000FX manufactured by JEOL Ltd. (acceleration voltage: 200 kV)

Time for electron beam irradiation: 5 seconds to 60 seconds

(Atomic Ratio in Depth Direction of Film Thickness from Surface of a Second Barrier Layer)

By comparing the XPS measurement (specifically, Si, O, and N) at each depth which is obtained by sputtering from a second barrier layer as described above and the results obtained from cross-sectional surface observation by TEM, the average value of O/Si and N/Si was calculated.

Furthermore, in the second barrier layer, a difference between an average abundance ratio of oxygen atoms to silicon atoms in a region from the outermost surface to a depth of 10 nm and an average abundance ratio of oxygen atoms to silicon atoms in a region from the outermost surface to a depth of more than 10 nm is preferably 0.4 or less. With this constitution, a change in composition decreases between a surface region and inside of a second barrier layer so that a gas barrier film having more excellent storage stability at high temperature and high moisture conditions is provided. The difference in average value is preferably 0.3 or less, and more preferably 0.2 or less.

The region from the outermost surface to a depth of 10 nm in a second barrier layer can be determined by X ray photoelectron spectroscopic method (XPS).

Furthermore, the average abundance ratio of oxygen atoms to silicon atoms in a region from the outermost surface to a depth of 10 nm and the average abundance ratio of oxygen atoms to silicon atoms in a region from the outermost surface to a depth of more than 10 nm can be calculated by a method combining the aforementioned Ar sputter etching apparatus and X ray photoelectron spectroscopic method (XPS).

The method for forming a second barrier layer as described above is, although not particularly limited, preferably a method in which a conversion treatment is performed by irradiating a layer containing polysilazane and a compound other than polysilazane (hereinbelow, also simply referred to as an addition compound) with active energy ray from the viewpoint productivity and simplicity. Hereinbelow, descriptions are given for a method for forming such a second barrier layer.

<Method for Forming a Second Barrier Layer>

The method for forming a second barrier layer is not particularly limited. However, preferred is a method in which a coating liquid for forming a second barrier layer containing an inorganic compound, preferably polysilazane, an addition compound, and, if necessary, a catalyst in an organic solvent is coated by a known wet type coating method, the solvent is removed by evaporation, and a conversion treatment is performed by irradiation of active energy ray such as ultraviolet ray, electron beam, X ray, α ray, β ray, γ ray, or neutron ray.

Specific examples of the polysilazane are as defined in the “first barrier layer” section described above, and thus no further descriptions are given therefor. Among them, from the viewpoint of having a film forming property and less defects such as cracks, less residual organic matters, and maintaining barrier performance during bending or under high temperature and high moisture conditions, perhydropolysilazane is particularly preferable.

Examples of the addition compound include at least one compound selected from the group consisting of water, an alcohol compound, a phenol compound, a metal alkoxide compound, an alkylamine compound, alcohol modified polysiloxane, alkoxy modified polysiloxane, and alkylamino modified polysiloxane. Among them, at least one compound selected from the group consisting of an alcohol compound, a phenol compound, a metal alkoxide compound, an alkylamine compound, an alcohol modified polysiloxane, alkoxy modified polysiloxane, and alkylamino modified polysiloxane is more preferable.

Specific examples of an alcohol compound which is used as an addition compound include methanol, ethanol, propanol, isopropanol, butanol, isobutanol, pentanol, isopentanol, hexanol, isohexanol, cyclohexyl alcohol, octanol, isooctanol, 2-ethylhexyl alcohol, nonyl alcohol, isononyl alcohol, tert-nonyl alcohol, decanol, dodecanol, dodecahexanol, dodecaoctanol, allyl alcohol, and oleyl alcohol. Because a Si—O—R bond is formed according to an occurrence of a dehydrogenation condensation reaction between Si—H group which may be contained in a polysilazane skeleton and OH group in an alcohol compound during conversion treatment in the case when an alcohol compound exists, the storage stability under high temperature and high moisture conditions is further improved. Among those alcohol compounds, methanol, ethanol, 1-propanol, or 2-propanol having low carbon number and boiling point of 100° C. or less is more preferable.

Specific examples of a phenol compound which is used as an addition compound include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, catechol, resorcinol, pyrogallol, α-naphtol, and β-naphtol. Like the alcohol compound, because a Si—O—R bond is formed according to an occurrence of a dehydrogenation condensation reaction between Si—H group which may be contained in a polysilazane skeleton and OH group in a phenol compound during conversion treatment in the case when a phenol compound exists, the storage stability under high temperature and high moisture conditions is further improved.

Examples of a metal alkoxide compound which is used as an addition compound include alkoxide of an element of Group 2 to Group 14 of long period type Periodic Table such as beryllium (Be), boron (B), magnesium (Mg), aluminum (Al), silicon (Si), calcium (Ca), scandium (Sc), titan (Ti), vanadium (V), chrome (Cr), manganese (Mn), iron (Fe), cobalt (Co), nickel (Ni), copper (Cu), zinc (Zn), gallium (Ga), germanium (Ge), strontium (Sr), yttrium (Y), zirconium (Zr), niobium (Nb), molybdenum (Mo), technetium (Tc), ruthenium (Ru), rhodium (Rh), palladium (Pd), silver (Ag), cadmium (Cd), indium (In), tin (Sn), barium (Ba), lanthanum (La), cerium (Ce), praseodymium (Pr), neodymium (Nd), promethium (Pm), samarium (Sm), eurofium (Eu), gadolinum (Gd), terbium (Tb), dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), yridium (Ir), platinum (Pt), gold (Au), mercury (Hg), thallium (Tl), lead (Pb), or radium (Ra).

More specific examples of the metal alkoxide compound include beryllium acetylacetonate, trimethyl borate, triethyl borate, tri n-propyl borate, triisopropyl borate, tri n-butyl borate, tri tert-butyl borate, magnesium ethoxide, magnesium ethoxyethoxide, magnesium methoxyethoxide, magnesium acetylacetonate, aluminum trimethoxide, aluminum triethoxide, aluminum tri n-propoxide, aluminum triisopropoxide, aluminum tri n-butoxide, aluminum tri sec-butoxide, aluminum tri tert-butoxide, aluminum acetylacetonate, acetoalkoxy aluminum diisopropylate, aluminum ethyl acetoacetate•diisopropylate, aluminum ethyl acetoacetate di n-butyrate, aluminum diethylacetoacetate mono n-butyrate, aluminum diisopropylate mono sec-butyrate, aluminum tris acetylacetonate, aluminum tris ethyl acetoacetate, bis(ethylacetoacetate) (2,4-pentanedionato)aluminum, aluminum alkylacetoacetate diisopropylate, aluminum oxide isopropoxide trimer, aluminum oxide octylate trimer, calcium methoxide, calcium ethoxide, calcium isopropoxide, calcium acetylacetonate, scandium acetylacetonate, titan tetra methoxide, titan tetra ethoxide, titan tetra normal propoxide, titan tetra isopropoxide, titan tetra normal butoxide, titan tetra isobutoxide, titan diisopropoxy dinormal butoxide, titan di tert-butoxydiisopropoxide, titan tetra tert-butoxide, titan tetra isooctyloxide, titan tetra stearylalkoxide, vanadium tri isobutoxide, tris(2,4-pentanedionato)chrome, chrome n-propoxide, chrome isopropoxide, manganese methoxide, tris(2,4-pentanedionato)manganese, iron methoxide, iron ethoxide, iron n-propoxide, iron isopropoxide, tris(2,4-pentanedionato)iron, cobalt isopropoxide, tris(2,4-pentanedionato)cobalt, nickel acetylacetonate, copper methoxide, copper ethoxide, copper isopropoxide, copper acetylacetonate, zinc ethoxide, zinc ethoxyethoxide, zinc methoxyethoxide, gallium methoxide, gallium ethoxide, gallium isopropoxide, gallium acetylacetonate, germanium methoxide, germanium ethoxide, germanium isopropoxide, germanium n-butoxide, germanium tert-butoxide, ethyltriethoxy germanium, strontium isopropoxide, yttrium n-propoxide, yttrium isopropoxide, yttrium acetylacetonate, zirconium ethoxide, zirconium n-propoxide, zirconium isopropoxide, zirconium butoxide, zirconium tert-butoxide, tetrakis(2,4-pentanedionato)zirconium, niobium ethoxide, niobium n-butoxide, niobium tert-butoxide, molybdenum ethoxide, molybdenum acetylacetonate, palladium acetylacetonate, silver acetylacetonate, cadmium acetylacetonate, tris(2,4-pentanedionato)indium, indium isopropoxide, indium isopropoxide, indiumn-butoxide, indium methoxyethoxide, tin n-butoxide, tin tert-butoxide, tin acetylacetonate, barium diisopropoxide, barium tert-butoxide, barium acetylacetonate, lanthanum isopropoxide, lanthanum methoxyethoxide, lanthanum acetylacetonate, cerium n-butoxide, cerium tert-butoxide, cerium acetylacetonate, praseodymium methoxyethoxide, praseodymium acetylacetonate, neodymium methoxyethoxide, neodymium acetylacetonate, neodymium methoxyethoxide, samarium isopropoxide, samarium acetylacetonate, eurofium acetylacetonate, gadolinum acetylacetonate, terbium acetylacetonate, holmium acetylacetonate, ytterbium acetylacetonate, lutetium acetylacetonate, hafnium ethoxide, hafnium n-butoxide, hafnium tert-butoxide, hafnium acetylacetonate, tantalum methoxide, tantalum ethoxide, tantalum n-butoxide, tantalum butoxide, tantalum tetra methoxide acetylacetonate, tungsten ethoxide, yridium acetylacetonate, yridium dicarbonyl acetylacetonate, thallium ethoxide, thallium acetylacetonate, lead acetylacetonate, and a compound having the following structure.

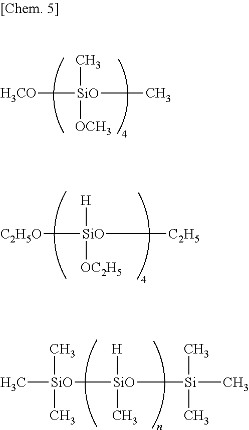

With the proviso that, n=an integer of from 1 to 10.

Furthermore, as a metal alkoxide compound, silsesquioxane can be also used.

Silsesquioxane is a siloxane-based compound having a main skeleton consisting of a Si—O bond. Silsesquioxane (also referred to as polysilsesquioxane) is also referred to as T resin and is a compound which is represented by general formula [RSiO_{1.5}] while common silica is represented by [SiO₂]. Generally, it is polysiloxane synthesized by hydrolysis-polycondensation of (RSi(OR′)₃) compound in which one alkoxy group of tetra alkoxysilane (Si(OR′)₄) represented by tetraethoxysilane is substituted with an alkyl group or an aryl group, and representative examples of the molecular arrangement include amorphous shape, ladder shape, and basket shape (fully condensed cage shape).

Silsesquioxane can be synthesized or a commercially available product can be used. Specific examples of the latter include X-40-2308, X-40-9238, X-40-9225, X-40-9227, x-40-9246, KR-500, KR-510 (all manufactured by Shin-Etsu Chemical Co., Ltd.), SR2400, SR2402, SR2405, FOX14 (perhydrosilsesquioxane) (all manufactured by Dow Corning Toray Co., Ltd.), and SST-H8H01 (perhydrosilsesquioxane) (manufactured by Gelest).

Among those metal alkoxide compounds, from the viewpoint of reactivity and solubility, a compound having a branch alkoxy group is preferable, and a compound having a 2-propoxy group or a sec-butoxy group is more preferable.

A metal alkoxide compound having an acetylacetonate group is also preferable. Due to the carbonyl structure, an acetylacetonate group has an interaction with a center element of an alkoxide compound, yielding better handlability. It is therefore preferable. A compound having plural alkoxide groups or acetylacetonate groups is more preferable from the viewpoint of reactivity or film composition.

The center element of metal alkoxide is preferably an element which can easily form a coordination bond with the nitrogen atom in polysilazane, and Al, Fe, or B having high Lewis acid property is more preferable.

Specific examples of the more preferred metal alkoxide compound include triisopropyl borate, aluminum tri sec-butoxide, aluminum ethylacetoacetate•diisopropylate, calcium isopropoxide, titan tetra isopropoxide, gallium isopropoxide, aluminum diisopropylate mono sec-butyrate, aluminum ethylacetoacetate di n-butyrate, and aluminum diethylacetoacetate mono n-butyrate.

The metal alkoxide compound can be synthesized or a commercially available product can be used. Specific examples a commercially available product include AMD (aluminum diisopropylate mono sec-butyrate), ASBD (aluminum secondary butyrate), ALCH (aluminum ethylacetoacetate•diisopropylate), ALCH-TR (aluminum tris ethylacetoacetate), aluminum chelate M (aluminum alkylacetoacetate•diisopropylate), aluminum chelate D (aluminum bisethylacetoacetate•mono acetylacetonate), aluminum chelate A (W) (aluminum tris acetylacetonate) (all manufactured by Kawaken Fine Chemicals Co., Ltd.), PLENACT (registered trademark) AL-M (acetoalkoxyaluminum diisopropylate, manufacturedby Ajinomoto Fine Chemicals Co., Ltd.), and Orgatics series (manufactured by Matsumoto Fine Chemical Co., Ltd.).

Meanwhile, for a case of using a metal alkoxide compound, it is preferable to mix it with a solution containing polysilazane under inert gas atmosphere to suppress progress of violent oxidation caused by reaction of a metal alkoxide compound with moisture or oxygen in atmosphere.

Specific examples of the alkylamine compound include a primary amine such as methylamine, ethylamine, propylamine, n-butylamine, sec-butylamine, tert-butylamine, or 3-morpholinopropylamine; a secondary amine such as dimethylamine, diethylamine, methylethylamine, dipropylamine, di(n-butyl)amine, di(sec-butyl)amine, or di(tert-butyl)amine; and a tertiary amine such as trimethylamine, triethylamine, dimethylethylamine, methyldiethylamine, tripropylamine, tri(n-butyl)amine, tri(sec-butyl)amine, tri(tert-butyl)amine, N,N-dimethylethanolamine, N,N-diethylethanolamine, or triethanolamine.

Further, as the alkylamine compound, a diamine compound can be used. Specific examples of the diamine compound include tetra methylmethanediamine, tetra methylethanediamine, tetra methylpropanediamine(tetra methyldiaminopropane), tetra methylbutanediamine, tetra methylpentanediamine, tetra methylhexanediamine, tetra ethylmethanediamine, tetra ethylethanediamine, tetra ethylpropanediamine, tetra ethylbutanediamine, tetra ethylpentanediamine, tetra ethylhexanediamine, N,N,N′,N′-tetra methyl-1,6-diaminohexane (TMDAH), and tetra methylguanidine.

Further, modified polysiloxane such as hydroxy modified polysiloxane having a hydroxyl group, alkoxy modified polysiloxane having an alkoxy group, or alkylamino modified polysiloxane having an alkylamino group can be also preferably used as an addition compound.

As for the modified polysiloxane, polysiloxanes that are represented by the following Formula (4) or Formula (5) can be preferably used.

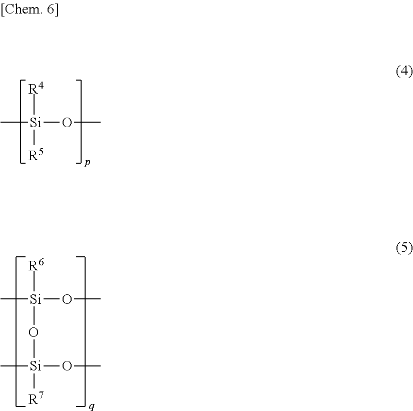

In Formula (4) or Formula (5), R⁴ to R⁷ each independently represent a hydrogen atom, a hydroxy group, an alkyl group, an alkenyl group, an alkynyl group, an alkoxy group, an alkylamino group, or a substituted or unsubstituted aryl group, in which at least one of R⁴ and R⁵ and at least one of R⁶ and R⁷ is a hydroxy group, an alkoxy group, or an alkylamino group, and p and q each independently represent an integer of 1 or more.

The modified polysiloxane can be synthesized or a commercially available product can be used. Specific examples of the commercially available product include X-40-2651, X-40-2655A, KR-513, KC-89S, KR-500, X-40-9225, X-40-9246, X-40-9250, KR-401N, X-40-9227, X-40-9247, KR-510, KR9218, KR-213, X-40-2308, and X-40-9238 (all manufactured by Shin-Etsu Chemical Co., Ltd.).

The conversion degree of a hydroxy group, an alkoxy group, or an alkylamino group in the modified polysiloxane is, relative to the molar number of silicon atoms, preferably 5 mol % to 50 mol %, more preferably 7 mol % to 20 mol %, and even more preferably 8 mol % to 12 mol %.

Weight average molecular weight of the modified polysiloxane, which is converted in terms of polystyrene, is preferably 1,000 to 100,000 or so, and more preferably 2,000 to 50,000 or so.

(Coating Liquid for Forming Second Barrier Layer)

A solvent for preparing a coating liquid for forming a second barrier layer is not particularly limited, as long as it can dissolve the polysilazane and addition compound described. However, an organic solvent not including water and a reactive group which easily react with polysilazane (for example, a hydroxyl group or an amine group) and being inert to the polysilazane is preferable. Aprotic organic solvent is more preferable. Specific examples of the solvent include an aprotic solvent; hydrocarbon solvent such as an aliphatic hydrocarbon, an alicyclic hydrocarbon or an aromatic hydrocarbon such as pentane, hexane, cyclohexane, toluene, xylene, solvesso, or terpene; a halogenated hydrocarbons such as methylene chloride, or trichloroethane; esters such as ethyl acetate and butyl acetate; ketones such as acetone and methyl ethyl ketone; ethers such as aliphatic ether and alicyclic ether such as dibutyl ether, dioxane, or tetra hydrofuran, for example, tetra hydrofuran, dibutyl ether, mono- and polyalkylene glycol dialkyl ether (diglymes). It may be used either singly or as a mixture of two or more types.

Although the polysilazane concentration in the coating liquid for forming a second barrier layer is not particularly limited and varies in accordance with the film thickness of the layer or the pot life of the coating liquid, it is preferably 1 to 80% by weight, more preferably 5 to 50% by weight, and particularly preferably 10 to 40% by weight.

Use amount of the addition compound in the coating liquid for forming a second barrier layer is preferably 1 to 50% by weight, and more preferably 1 to 15% by weight relative to polysilazane. When it is within this range, the second barrier layer according to the present invention can be efficiently obtained.

In order to promote the conversion, a catalyst is preferably contained in a coating liquid for forming the second barrier layer. As a catalyst which can be applied for the present invention, a basic catalyst is preferable. In particular, an amine catalyst such as N,N-diethylethanolamine, N,N-dimethylethanolamine, triethanolamine, triethylamine, 3-morpholino propylamine, N,N,N′,N′-tetra methyl-1,3-diaminopropane, or N,N,N′,N′-tetra methyl-1,6-diaminohexane, a metal catalyst including a Pt compound such as Pt acetyl acetonate, a Pd compound such as Pd propionate, and a Rh compound such as Rh acetylacetonate, and an N-heterocyclic compound can be exemplified. Among them, it is preferable to use an amine catalyst. While taking the silicon compound as a reference, a concentration of the catalyst to be added is preferably within a range of 0.1 to 10% by weight, more preferably within a range of 0.5 to 7% by weight. By having an addition amount of the catalyst within the range, having an excessive forming amount of silanol, a decrease in film density, and an increase in film defects that are caused by a rapid progress of the reaction can be avoided. Meanwhile, among those catalysts, the amine catalyst can also play a role of the addition compound.

If necessary, the following additives can be used in a coating liquid for forming a second barrier layer. Examples include cellulose ethers, cellulose esters; for example, ethylcellulose, nitrocellulose, cellulose acetate, and cellulose acetobutyrate, natural resins; for example, rubbers and rosin resins, synthetic resins; for example, polymerized resins, condensed resins; for example, aminoplast, in particular, urea resin, melamine formaldehyde resin, alkyd resin, acrylic resin, polyester or modified polyester, epoxide, polyisocyanate, or blocked polyisocyanate, and polysiloxane.

(Method for Coating a Coating Liquid for Forming Second Barrier Layer)

As for the method of applying a coating liquid for forming a second barrier layer, any suitable known wet coating method may be used. Specific examples thereof include a spin coating method, a roll coating method, a flow coating method, an inkjet method, a spray coating method, a printing method, a dip coating method, a cast film forming method, a bar coating method, and Gravure printing method.

The coating thickness can be suitably set depending on the purpose. For example, the coating thickness per one layer of the second barrier layer is preferably 10 nm to 10 μm, more preferably 15 nm to 1 μm, and even more preferably 20 to 500 nm in terms of thickness after drying. When the film thickness is 10 nm or more, a sufficient barrier property can be obtained. On the other hand, when it is 10 μm or less, a stable coating property can be obtained during layer forming and also high light transmission can be achieved.

The method for drying a coating film after coating a coating liquid, drying temperature, drying time, and drying atmosphere are as defined in the “first barrier layer” section described above, and thus no further descriptions are given therefor.

Furthermore, the method for removing moisture from a coating film obtained by coating a coating liquid for forming the second coating layer is as defined in the “first barrier layer” section described above, and thus no further descriptions are given therefor.

The preferred method for converting an obtained coating film is as defined in (Ultraviolet ray irradiation treatment) and (Vacuum ultraviolet ray irradiation treatment: Excimer irradiation treatment) of the “first barrier layer” section described above, and thus no further descriptions are given therefor.

In the vacuum ultraviolet ray irradiation process, illuminance of the vacuum ultraviolet ray on a coating film which has been formed with a coating liquid for forming a second barrier layer is preferably 1 mW/cm² to 10 W/cm², more preferably 30 mW/cm² to 200 mW/cm², and even more preferably 50 mW/cm² to 160 mW/cm². When the illuminance is lower than 1 mW/cm², the conversion efficiency may be greatly lowered. On the other hand, when it is higher than 10 W/cm², an ablation may occur on a coating film or a substrate may suffer from damage.

An irradiation energy amount (irradiation amount) of the vacuum ultraviolet ray on a coating film which has been formed with a coating liquid for forming a second barrier layer is preferably 10 to 10,000 mJ/cm², more preferably 100 to 8,000 mJ/cm², and even more preferably 200 to 6,000 mJ/cm². When it is lower than 10 mJ/cm², the conversion may become insufficient. On the other hand, when it is higher than 10,000 mJ/cm², an occurrence of cracks caused by excessive conversion or substrate deformation caused by heat may occur.

Further, the film density of a second barrier layer can be suitably set depending on the object. For example, the film density of a second barrier layer is preferably within a range of from 1.5 to 2.6 g/cm³. When it is not within this range, deterioration of a barrier property due to decreased film density or film oxidation deterioration caused by moisture may occur.

The second barrier layer may be a single layer or has a laminated structure in which two or more layers are present.

For a case in which the second barrier layer has a laminated structure in which two or more layers are present, each second barrier layer may have the same or difference composition.

Furthermore, in the second barrier layer, an abundance ratio of oxygen atoms to silicon atoms, an abundance ratio of nitrogen atoms to silicon atoms, and a difference between an average abundance ratio of oxygen atoms to silicon atoms in a region from the outermost surface to a depth of 10 nm and an average abundance ratio of oxygen atoms to silicon atoms in a region from the outermost surface to a depth of more than 10 nm can be controlled by type and amount of polysilazane and an addition compound that are used for forming a second barrier layer, and conditions for converting a layer containing polysilazane and an addition compound, and the like.

[Intermediate Layer]

The gas barrier film of the present invention may have an intermediate layer between the first barrier layer and the second barrier layer for the purpose of alleviating stress or the like. As a method for forming an intermediate layer, a method for forming a polysiloxane modified layer can be applied. According to this method, a coating liquid containing polysiloxane is coated on top of a first barrier layer by a wet coating method followed by drying, and the obtained dry coating film is irradiated with vacuum ultraviolet ray to form an intermediate layer.

As a coating liquid which is used for forming an intermediate layer, a liquid containing polysiloxane and an organic solvent is preferable.

The polysiloxane applicable for forming an intermediate layer is not particularly limited, but organo polysiloxane represented by the following Formula (6) is particularly preferable.

In this embodiment, examples are given for a case in which organo polysiloxane represented by the following Formula (6) is used as polysiloxane.

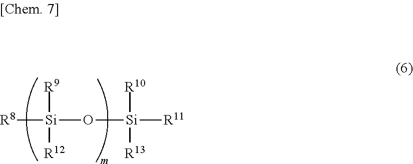

In the above Formula (6), R⁸ to R¹³ each independently represent an organic group with 1 to 8 carbon atoms. In this case, at least one of R⁸ to R¹³ is an alkoxy group or a hydroxyl group, and m is an integer of 1 or more.

Examples of the organic group with 1 to 8 carbon atoms expressed by R⁸ to R¹³ include: a halogenated alkyl group such as a γ-chloropropyl group or 3,3,3-trifluoropropyl group; a vinyl group; a phenyl group; a (meth)acrylic acid ester group such as a γ-methacryloxypropyl group; an epoxy-containing alkyl group such as a γ-glycidoxypropyl group; a mercapto-containing alkyl group such as a γ-mercaptopropyl group; an aminoalkyl group such as a γ-aminopropyl group; an isocyanate-containing alkyl group such as a γ-isocyanate propyl group; a linear or branched alkyl group such as a methyl group, an ethyl group, a n-propyl group, or an isopropyl group; an alicyclic alkyl group such as a cyclohexyl group or a cyclopentyl group; a linear or branched alkoxy group such as a methoxy group, an ethoxy group, a n-propoxy group, or an isopropoxy group; and an acyl group such as an acetyl group, a propionyl group, a butyryl group, a valeryl group, or a caproyl group, and a hydroxyl group.

Regarding Formula (6), it is more preferable to use organopolysiloxane in which m is 1 or more and a weight average molecular weight (in terms of polystyrene) is 1,000 to 20,000. When the weight average molecular weight of organopolysiloxane is 1,000 or more, cracks hardly occur in the protective layer to be formed, and thus the gas barrier property can be maintained. Meanwhile, when the weight average molecular weight of organopolysiloxane is 20,000 or less, curing of the protective layer to be formed becomes sufficient, and thus sufficient hardness can be obtained for the protective layer.

Examples of the organic solvent which can be employed for forming an intermediate layer include an alcohol solvent, a ketone solvent, an amide solvent, an ester solvent, and an aprotic solvent.

Herein, examples of the preferred alcohol solvent include n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, propylene glycol monomethyl ether, propylene glycol monoethyl ether, propylene glycol monopropyl ether, and propylene glycol monobutyl ether.

Examples of the ketone solvent include acetone, methyl ethyl ketone, methyl-n-propyl ketone, methyl-n-butyl ketone, diethyl ketone, methyl-iso-butyl ketone, methyl-n-pentyl ketone, ethyl-n-butyl ketone, methyl-n-hexyl ketone, di-iso-butyl ketone, trimethylnonanone, cyclohexanone, 2-hexanone, methylcyclohexanone, 2,4-pentane dione, acetonyl acetone, acetophenone, penchone, and also β-diketones such as acetylacetone, 2,4-hexanedione, 2,4-heptanedione, 3,5-heptanedione, 2,4-otcanedione, 3,5-octanedione, 2,4-nonanedione, 3,5-nonanedione, 5-methyl-2,4-hexanedione, 2,2,6,6-tetra methyl-3,5-heptanedione, and 1,1,1,5,5,5-hexafluoro-2,4-heptanedione. The ketone solvent can be used either singly or in combination of two or more types.

Examples of the amide solvent include formamide, N-methyl formamide, N,N-dimethyl formamide, N-ethyl formamide, N,N-diethyl formamide, acetamide, N-methyl acetamide, N,N-dimethyl acetamide, N-ethylacetamide, N,N-diethyl acetamide, N-methyl propionamide, N-methyl pyrrolidone, N-formyl morpholine, N-formyl piperidine, N-formyl pyrrolidine, N-acetylmorpholine, N-acetylpiperidine, and N-acetylpyrrolidine. The amide solvent can be used either singly or in combination of two or more types.

Examples of the ester solvent include diethyl carbonate, ethylene carbonate, propylene carbonate, diethyl carbonate, methyl acetate, ethyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, acetic acid ethylene glycol monomethyl ether, acetic acid ethylene glycol monoethyl ether, acetic acid diethylene glycol monomethyl ether, acetic acid diethylene glycol monoethyl ether, acetic acid diethylene glycol mono-n-butyl ether, acetic acid propylene glycol monomethyl ether, acetic acid propylene glycol monoethyl ether, acetic acid propylene glycol monopropyl ether, acetic acid propylene glycol monobutyl ether, acetic acid dipropylene glycol monomethyl ether, acetic acid dipropylene glycol monoethyl ether, diacetic acid glycol, acetic acid methoxy triglycol, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate. The ester solvent can be used either singly or in combination of two or more types.

Examples of the aprotic solvent include acetonitrile, dimethyl sulfoxide, N,N,N′,N′-tetra ethyl sulfamide, hexamethylphosphoric acid triamide, N-methylmorpholone, N-methylpyrrole, N-ethylpyrrole, N-methylpiperidine, N-ethylpiperidine, N,N-dimethyl piperazine, N-methylimidazole, N-methyl-4-piperidone, N-methyl-2-piperidone, N-methyl-2-pyrrolidone, 1,3-dimethyl-2-imidazolidinone, and 1,3-dimethyl tetrahydro-2(1H)-pyrimidinone. The aprotic solvent can be used either singly or in combination of two or more types.

As for the organic solvent which is used for forming an intermediate layer, the alcohol solvent is preferred among the aforementioned organic solvents.

Examples of the method of forming an intermediate layer include a spin coating method, dipping method, a roller blade method, and a spray method.

Thickness of an intermediate layer which is formed of a coating liquid for forming an intermediate layer is preferably in the range of form 100 nm to 10 μm. When the thickness of an intermediate layer is 100 nm or more, a gas barrier property under high temperature and high moisture conditions can be obtained. Furthermore, when the thickness of an intermediate layer is 10 μm or less, a stable coating property can be obtained during forming an intermediate layer and also high light transmission can be achieved.

Furthermore, the intermediate layer has film density of generally 0.35 to 1.2 g/cm³, preferably 0.4 to 1.1 g/cm³, and more preferably 0.5 to 1.0 g/cm³. When the film density is 0.35 g/cm or higher, the coating film can have sufficient mechanical strength.

The intermediate layer according to the present invention is formed by coating a coating liquid containing polysiloxane on a first barrier layer by a wet coating method followed by drying and irradiating the dried coating film (polysiloxane coating film) with vacuum ultraviolet ray.

As for the vacuum ultraviolet ray which is used for forming an intermediate layer, the vacuum ultraviolet ray for vacuum ultraviolet ray irradiation treatment which has been described in relation to forming of a barrier layer described above can be used.

Integrated light amount of the vacuum ultraviolet ray for forming an intermediate layer by conversion of polysiloxane film is preferably 500 mJ/cm² to 10,000 mJ/cm² in the present invention. When the integrated light amount of the vacuum ultraviolet ray is 500 mJ/cm² or more, sufficient gas barrier performance can be obtained. When it is 10,000 mJ/cm² or less, an intermediate layer with high smoothness can be obtained without having a deformation on a substrate.

Furthermore, the intermediate layer according to the present invention is preferably formed via a heating step in which the heating temperature is 50° C. to 200° C. When the heating temperature is 50° C. or higher, a sufficient barrier property can be obtained. When it is 200° C. or lower, an intermediate layer with high smoothness can be formed without having a deformation on a substrate. For the heating process, a heating method using a hot plate, an oven, a furnace or the like can be applied. Furthermore, the drying atmosphere can be any one condition including air atmosphere, nitrogen atmosphere, argon atmosphere, vacuum atmosphere, and reduced pressure atmosphere with controlled oxygen concentration.

For example, it is also possible that a polysiloxane coating film is formed on a coating film of polysilazane before conversion, which has been formed during forming of a first barrier layer, the polysilazane coating film and polysiloxane coating film are simultaneously irradiated with vacuum ultraviolet ray, and a heating treatment is performed at 100° C. to 250° C. to form a first barrier layer and an intermediate layer. It is also possible that a polysiloxane coating film is formed on a coating film of polysilazane, which has been undergone with a vacuum ultraviolet ray irradiation treatment, the polysiloxane coating film is irradiated with vacuum ultraviolet ray, and a heating treatment is performed at 100° C. to 250° C. to form a first barrier layer and an intermediate layer.

As described above, when a heating treatment at 100° C. or higher is performed for a state in which the polysilazane coating film (which becomes a first barrier layer) is covered with a polysiloxane coating film (which becomes an intermediate layer), an occurrence of tiny cracks in a first barrier layer as caused by heat stress of a heating treatment can be prevented, and thus the barrier performance of a first barrier layer can be stabilized.

[Protective Layer]

The gas barrier film according to the present invention can be formed with a protective layer containing an organic compound on top of a second barrier layer. As for the organic compound which is used for a protective layer, an organic resin such as organic monomer, oligomer, or polymer, or an organic-inorganic composite resin layer using monomer, oligomer, or polymer of siloxane or silsesquioxane having an organic group or the like can be preferably used.

[Desiccant-Like Layer]

The gas barrier film according to the present invention may also have a desiccant-like layer (moisture adsorbing layer). Examples of a material which is used for a desiccant-like layer include calcium oxide and organic metal oxide. As for the calcium oxide, those dispersed in a binder rein or the like are preferable. Preferred commercially available products which can be used include AqvaDry (registered trademark) series manufactured by SAES Getters S.p.A. Further, as for the organic metal oxide, OleDry (registered trademark) series manufactured by Futaba Corporation can be used.

[Smooth Layer (Underlayer, Primer Layer)]

The gas barrier film according to the present invention may have a smooth layer (underlayer, primer layer) on a substrate surface having a barrier layer, preferably between a substrate and a first gas barrier layer. The smooth layer is provided for flattening the rough surface of a substrate, on which projections and the like are present, or flattening a barrier layer by filling up unevenness and pinholes generated thereon by projections present on the substrate. Such a smooth layer can be formed of any material. However, it preferably contains a carbon-containing polymer, and more preferably, it consists of a carbon-containing polymer. Specifically, it is preferable that the gas barrier film of the present invention further have a smooth layer containing a carbon-containing polymer between a substrate and a first barrier layer.

Furthermore, the smooth layer contains a carbon-containing polymer, and preferably a thermosetting resin. The thermosetting resin is not particularly limited, and examples thereof include an active energy ray setting resin which is obtained by irradiating an active energy ray setting resin with active energy ray such as ultraviolet ray and a thermosetting resin which is obtained by heating and setting a thermosetting material. The setting resin can be used either singly or in combination of two or more types.

Examples of the active energy ray setting material used for forming of the smooth layer include a resin composition containing an acrylate, a resin composition containing an acrylate compound and a mercapto compound having a thiol group, and a composition containing a polyfunctional acrylate monomer such as epoxy acrylate compound, urethane acrylate, polyester acrylate, polyether acrylate, polyethylene glycol acrylate, or glycerol methacrylate. Specifically, a UV curable organic/inorganic hybrid hard coating material OPSTAR (registered trademark) series (a compound obtained by binding an organic compound having a polymerizable unsaturated group to silica microparticles) manufactured by JSR Corporation may be used. Further, any mixture of the compositions described above can also be used, and it is not particularly limited as long as it is an active energy ray setting material containing a reactive monomer having at least one photopolymerizable unsaturated bond in a molecule.

The method of forming the smooth layer is not particularly limited, but a method in which a coating film is formed by coating a coating liquid containing a setting material by a wet coating method such as a spin coating method, a spray coating method, a blade coating method, a dipping method, or a Gravure printing method, or a dry coating method such as a vapor deposition method, and the coating film is set and formed by irradiation of active energy ray such as visible ray, infrared ray, ultraviolet ray, X ray, α ray, β ray, γ ray, or electron beam and/or by heating is preferable. Meanwhile, as a method for applying active energy ray, mention can be made for a method in which ultraviolet ray having a wavelength in a range preferably of 100 to 400 nm and more preferably of 200 to 400 nm is irradiated by using an ultra-high pressure mercury lamp, a high pressure mercury lamp, a low pressure mercury lamp, a carbon arc, a metal halide lamp or the like, or electron beam having a wavelength in a range of 100 nm or less, which is emitted from a scan type or curtain type electron beam accelerator, is irradiated.

The smoothness of the smooth layer is a value expressed by a surface roughness defined in JIS B 0601:2001 and the maximum cross-sectional height Rt (p) is preferably 10 nm to 30 nm.

The surface roughness is measured employing an AFM (atomic force microscope), specifically from a cross-sectional curve of irregularities that is continuously measured by a detector having a probe with extremely small tip radius, and it indicates the roughness regarding amplitude of tiny irregularities after measuring several times a region with measurement direction of several tens of micrometers by a probe with extremely small tip radius.

Film thickness of the smooth layer is, although not particularly limited, preferably in a range of 0.1 to 10 μm.

[Anchor Coat Layer]

On a surface of the substrate according to the present invention, an anchor coat layer can be formed as an easy adhesion layer for the purpose of enhancing the adhesiveness (adhesion). Examples of the anchor coat agent used for the anchor coat layer include a polyester resin, an isocyanate resin, a urethane resin, an acryl resin, an ethylene•vinyl alcohol resin, a vinyl modified resin, an epoxy resin, a modified styrene resin, a modified silicon resin, and alkyl titanate, and one type or two or more types thereof can be used. As an anchor coat agent, a commercially available product can be used. Specifically, a siloxane-based ultraviolet ray curable polymer solution (3% isopropyl alcohol solution of X-12-2400 manufactured by Shin-Etsu Chemical Co., Ltd.) can be used.

A known additive can be added to the anchor coat agent. Further, coating of the anchor coat agent can be performed by coating on a substrate by a known method such as roll coating, Gravure coating, knife coating, dip coating, and spray coating, and drying and removing a solvent, a diluent, or the like. The coating amount of the anchor coat agent is preferably 0.1 to 5 g/m² or so (in dry state). Meanwhile, a commercially available substrate adhered with an easy adhesion layer can be also used.

Alternatively, the anchor coat layer can be also formed by a vapor phase method such as physical vapor deposition method or chemical vapor deposition method. For example, as described in JP 2008-142941A, an inorganic film having silicon oxide as a main component can be formed for the purpose of improving adhesiveness or the like.

Furthermore, thickness of the anchor coat layer is, although not particularly limited, preferably 0.5 to 10 μm or so.

[Bleed-Out Preventing Layer]

In the gas barrier film of the present invention, a bleed-out preventing layer can be further included. The bleed-out preventing layer is provided on the opposite surface of the substrate having a smooth layer for the purpose of suppressing such a phenomenon that unreacted oligomers and so on are transferred from the interior to the surface of the film substrate to contaminate the contact surface when the film having the smooth layer is heated. The bleed-out preventing layer may have essentially the same structure as that of the smooth layer as long as it has the function described above.

As a compound which can be included in the bleed-out preventing layer, a hard coating agent such as a polyvalent unsaturated organic compound having two or more polymerizable unsaturated groups in a molecule or a monovalent unsaturated organic compound having one polymerizable unsaturated group in a molecule can be mentioned.

Here, examples of the polyvalent unsaturated organic compound include ethylene glycol di(meth)acrylate, diethylene glycol di(meth)acrylate, glycerol di(meth)acrylate, glycerol tri(meth)acrylate, 1,4-butanediol di(meth)acrylate, 1,6-hexanediol di(meth)acrylate, neopentyl glycol di(meth)acrylate, trimethylol propane tri(meth)acrylate, dicyclopentanyl di(meth)acrylate, pentaerythritol tri(meth)acrylate, pentaerythritol tetra(meth)acrylate, dipentaerythritol hexa(meth)acrylate, dipentaerythritol monohydroxypenta(meth)acrylate, ditrimethylol propanetetra(meth)acrylate, diethylene glycol di(meth)acrylate, polyethylene glycol di(meth)acrylate, tripropylene glycol di(meth)acrylate, and polypropylene glycol di(meth)acrylate.

Furthermore, examples of the monovalent unsaturated organic compound include methyl(meth)acrylate, ethyl(meth)acrylate, propyl(meth)acrylate, butyl(meth)acrylate, 2-ethylhexyl(meth)acrylate, isodecyl(meth)acrylate, lauryl(meth)acrylate, stearyl(meth)acrylate, allyl(meth)acrylate, cyclohexyl(meth)acrylate, methylcyclohexyl(meth)acrylate, isobornyl(meth)acrylate, 2-hydroxyethyl(meth)acrylate, 2-hydroxypropyl(meth)acrylate, glycerol(meth)acrylate, glycidyl(meth)acrylate, benzyl(meth)acrylate, 2-ethoxyethyl(meth)acrylate, 2-(2-ethoxyethoxyl)ethyl(meth)acrylate, butoxyethyl(meth)acrylate, 2-methoxyethyl(meth)acrylate, methoxydiethylene glycol(meth)acrylate, methoxytriethylene glycol(meth)acrylate, methoxypolyethylene glycol(meth)acrylate, 2-methoxypropyl(meth)acrylate, methoxydipropylene glycol(meth)acrylate, methoxytripropylene glycol(meth)acrylate, methoxypolypropylene glycol(meth)acrylate, polyethylene glycol(meth)acrylate, and polypropylene glycol(meth)acrylate.

As other additives, a matting agent may be contained. As the matting agent, inorganic particles having an average particle diameter of about 0.1 to 5 μm are preferable.

As these inorganic particles, silica, alumina, talk, clay, calcium carbonate, magnesium carbonate, barium sulfate, aluminum hydroxide, titanium dioxide, zirconium oxide and the like can be used alone or in combination of two or more thereof.

The thickness of the bleed-out preventing layer is preferably 1 to 10 μm and more preferably 2 to 7 μm. By ensuring that the thickness is 1 μm or more, the heat resistance as a film is easily made sufficient, and by ensuring that the thickness is 10 μm or less, the balance of the optical characteristics of the smooth film is easily adjusted and curls of the barrier film can be easily suppressed in a case in which the smooth layer is provided on one surface of the transparent polymer film.

<<Package Configuration of Gas Barrier Film>>

The gas barrier film of the present invention can be produced continuously and wound in the form of a roll (so-called roll-to-roll process). At this time, it is preferable to wind the film with a protective sheet bonded to a surface on which a barrier layer is formed. Particularly, when the gas barrier film of the embodiment according to the invention is used as a sealing material for an organic thin film device, there are many cases where defects are caused by contaminants (particles) deposited on the surface and it is very effective to prevent deposition of contaminants by bonding a protective sheet in a place where the cleanliness level is high. At the same time, scratches generated on the surface of the gas barrier layer at the time of winding the film are effectively prevented.

The protective sheet is not particularly limited, but a general “protective sheet” or “peel-off sheet” having a structure in which a resin substrate having a thickness of about 100 μm is provided with a weak-adhesive adhesion layer can be used.

[Electronic Device]

The gas barrier film of the present invention can be preferably used for a device of which performance is deteriorated by chemical components in the air (oxygen, water, nitrogen oxides, sulfur oxides, ozone, or the like). Examples of the device include an organic EL element, a liquid crystal display element (LCD), a thin film transistor, a touch panel, an electronic paper, and a solar cell (PV). From the viewpoint of obtaining more efficiently the effect of the present invention, it is preferably used for an organic EL element or a solar cell, and particularly preferably for an organic EL element.

The gas barrier film of the present invention can be also used for film sealing of a device. Specifically, it relates to a method for forming a gas barrier film of the present invention on a surface of a device itself as a support. It is also possible that the device is covered with a protective layer before forming a gas barrier film.

The gas barrier film of the present invention can be also used as a substrate of a device or as a film for sealing by solid sealing method. The solid sealing method indicates a method in which a protective layer is formed on a device and a protective layer and a gas barrier film are overlaid followed by setting. The adhesive is not particularly limited, and examples thereof include a thermosetting epoxy resin and a photocurable acrylate resin.

<Organic EL Element>

Examples of an organic EL element using a gas barrier film are described in detail in JP 2007-30387 A.

<Liquid Crystal Display Element>

A reflection type liquid crystal display element has a configuration in which, in the order from the bottom, a base plate, a reflective electrode, a lower orientation film, a liquid crystal layer, an upper orientation film, a transparent electrode, a top plate, a λ/4 plate, and a polarizing plate are included. The gas barrier film of the present invention can be used as a transparent electrode substrate or a top plate. In the case of color display, it is preferable that a color filter layer be further formed between a reflective electrode and a lower orientation film, or between an upper orientation film and a transparent electrode. A transmission type liquid crystal display element has a configuration in which, in the order from the bottom, a backlight, a polarizing plate, a λ/4 plate, a lower transparent electrode, a lower orientation film, a liquid crystal layer, an upper orientation film, an upper transparent electrode, a top plate, a λ/4 plate, and a polarizing plate are included. In the case of color display, it is preferable that a color filter layer be further formed between a lower transparent electrode and a lower orientation film, or between an upper orientation film and a transparent electrode. Type of a liquid crystal is not particularly limited, but it is preferably TN type (Twisted Nematic), STN type (Super Twisted Nematic) or HAN type (Hybrid Aligned Nematic), VA type (Vertically Alignment), ECB type (Electrically Controlled Birefringence), OCB type (Optically Compensated Bend), IPS type (In-Plane Switching), or CPA type (Continuous Pinwheel Alignment).

<Solar Cell>

The gas barrier film of the present invention can be also used as a sealing film of a solar cell element. Herein, it is preferable that the gas barrier film of the present invention be sealed such that the barrier layer is present close to a solar cell element. The solar cell element for which the gas barrier film of the present invention is preferably used is not particularly limited, but examples thereof include a monocrystal silicon solar cell element, a polycrystal silicon solar cell element, an amorphous silicon solar cell element containing a single attachment type, a tandem structure type or the like, a Group III-V compound semiconductor solar cell element with gallium arsenic (GaAs), indium phosphorus (InP) or the like, Group II-VI compound semiconductor solar cell element with cadmium tellurium (CdTe) or the like, Group I-III-VI compound semiconductor solar cell element with copper/indium/selenium system (so called, CIS system), copper/indium/gallium/selenium system (so called, CIGS system), copper/indium/gallium/selenium/sulfur system (so called, CIGSS system) or the like, a dye sensitized solar cell element, and an organic solar cell element. Among them, in the present invention, it is preferable that the solar cell element be a Group I-III-VI compound semiconductor solar cell element such as copper/indium/selenium system (so called, CIS system), copper/indium/gallium/selenium system (so called, CIGS system), or copper/indium/gallium/selenium/sulfur system (so called, CIGSS system) or the like.

<Others>

Other application examples include a thin film transistor describedin JP10-512104W, a touch panel described in JP 5-127822 A, JP 2002-48913A, or the like, and an electronic paper described in JP 2000-98326 A.

<Optical Member>

The gas barrier film of the present invention can be also used as an optical member. Examples of the optical member include a circularly polarizing plate.

(Circularly Polarizing Plate)

By using the gas barrier film of the present invention as a substrate, and laminating a λ/4 plate and a polarizing plate, a circularly polarizing plate can be produced. In that case, the lamination is performed such that the slow phase axis of a λ/4 plate and an absorption axis of a polarizing plate form an angle of 45°. As for the polarizing plate, those stretched in 45° direction relative to the length direction (MD) are preferably used, and for example those described in JP 2002-865554 A can be preferably used.

### Examples

Hereinbelow, the effect of the present invention is described specifically by referring to Examples and Comparative Examples given below, however, the technical scope of the present invention is not limited to Examples. In Examples, the term “parts” or “%” is used. Unless particularly mentioned, this represents “parts by weight” or “% by weight”. Furthermore, regarding the following operations, the operations and measurements of physical properties or the like are performed under conditions of room temperature (20 to 25° C.)/relative humidity of 40 to 50%, unless specifically described otherwise.

[Forming of a First Barrier Layer (Coating Method)]

(Preparation of coating liquid containing polysilazane)

The coating liquid was prepared by diluting as follows: a dibutyl ether solution containing 20% by weight of non-catalytic perhydropolysilazane (AQUAMICA (registered trademark) NN120-20, produced by AZ electronic materials Co., Ltd.) and a dibutyl ether solution containing 20% by weight perhydropolysilazane with an amine catalyst (N,N,N′,N′-tetramethyl-1,6-diaminohexane (TMDAH)) (AQUAMICA (registered trademark) NAX120-20, produced by AZ electronic materials Co., Ltd.) were mixed at a ratio of 4:1, and with a solvent in which dibutyl ether and 2,2,4-trimethylpentane are mixed to have a weight ratio of 65:35, they were diluted such that the solid content of the coating liquid is 5% by weight.

By using a spin coater, the coating liquid obtained from above was formed as a film with thickness of 300 nm on a PET substrate (thickness of 125 μm) applied with a clear hard coat manufactured by KIMOTO CO., Ltd. After allowing it to stand for 2 minutes, it was subjected to a further heating treatment on a hot plate at 80° C. for 1 minute to form a polysilazane coating film.

After forming a polysilazane coating film, vacuum ultraviolet ray irradiation of 6000 mJ/cm² was performed to form a first barrier layer.

<Conditions for Vacuum Ultraviolet Ray Irradiation•Measurement of Irradiation Energy>

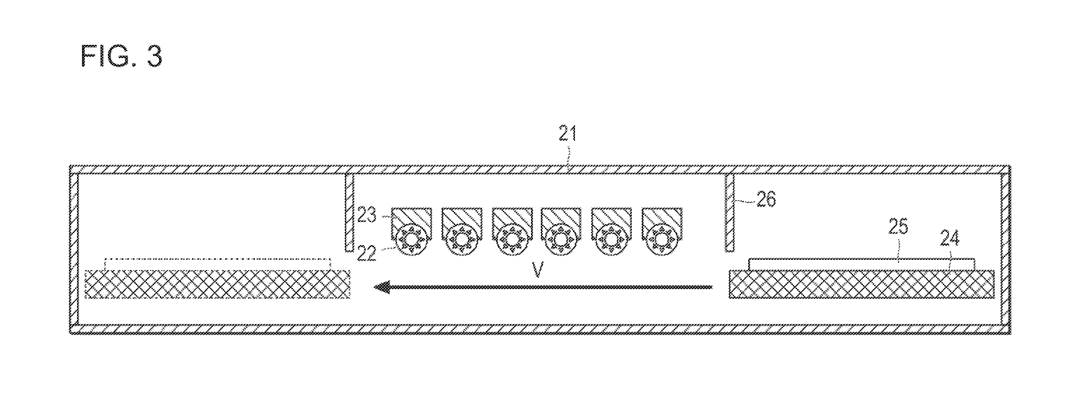

Irradiation of vacuum ultraviolet ray was performed by using the apparatus which schematically illustrated in FIG. 3.

In FIG. 3, 21 represents an apparatus chamber, and by supplying a suitable amount of nitrogen and oxygen from a non-illustrated gas inlet to the inside and discharging it through a non-illustrated gas outlet, water vapor is substantially removed from the inside of the chamber so that oxygen concentration can be maintained at a pre-determined concentration. 22 represents a Xe excimer lamp with a double-tubular structure which applies irradiation of vacuum ultraviolet ray of 172 nm, and 23 represents a holder of an examiner lamp, functioning also as an external electrode. 24 represents a sample stage. Sample stage 24 can move back and forth horizontally at a pre-determined speed within the apparatus chamber 21 by a non-illustrated means for transport. Further, sample stage 24 can be maintained at a pre-determined temperature by a non-illustrated heating means. 25 represents a sample with polysilazane coating film formed thereon. Height of the sample stage is adjusted such that, when the sample stage moves horizontally, the shortest distance between coating layer surface on the sample and the tubular surface of the excimer lamp is 3 mm. 26 represents a light shielding plate, and it prevents irradiation of vacuum ultraviolet rayon a coating layer on the sample during aging of a Xe excimer lamp 22.

The energy irradiated on the coating layer surface by the vacuum ultraviolet ray irradiation process was measured by using an ultraviolet integrated actinometer C8026/H8025 UV POWER METER manufactured by Hamamatsu Photonics K.K. and a sensor head of 172 nm. For the measurement, the sensor head was set at the center of the sample stage 24 such that the shortest distance between the tubular surface of the Xe excimer lamp and the measurement surface of the sensor head is 3 mm. Further, nitrogen and oxygen were fed such that the atmosphere inside the apparatus chamber 21 has the same oxygen concentration as the vacuum ultraviolet ray irradiation process and the sample stage 24 was moved at the rate of 0.5 m/min (V in FIG. 3) to perform the measurement. Before the measurement, to stabilize the illuminance of the Xe excimer lamp 12, aging time of 10 min was allowed after lighting the Xe excimer lamp. After that, by moving the sample stage, the measurement was initiated.

Based on the irradiation energy obtained from the above measurement, an adjustment was made to have the irradiation energy of 6000 mJ/cm² by adjusting the movement rate of the sample stage. Meanwhile, for the vacuum ultraviolet ray irradiation, it was performed after aging time of 10 min, similarly to the measurement of irradiation energy.

[Forming of a First Barrier Layer (Plasma CVD Method)]

The PET substrate (thickness of 125 μm) applied with a clear hard coat manufactured by KIMOTO CO., Ltd. was set in the manufacturing apparatus 31 illustrated in FIG. 2 and conveyed. Subsequently, while simultaneously applying magnetic field between the film forming roller 39 and the film forming roller 40, electric power was supplied to each of the film forming roller 39 and the film forming roller 40, and plasma was generated according to discharge between the film forming roller 39 and the film forming roller 40. Subsequently, mixed gas of film forming gas (hexamethyldisiloxane (HMDSO) as rawmaterial gas) and oxygen gas as reaction gas (also functions as discharge gas) was supplied to the formed discharge region, and by forming a thin film with a gas barrier property (first barrier layer) by a plasma CVD method on the substrate 2, a gas barrier film was obtained. Thickness of the first barrier layer was 150 nm. The film forming conditions were as described below.

(Conditions for Film Forming)

Supply amount of raw material gas: 50 sccm (Standard Cubic Centimeter per Minute, 0° C., 1 atmospheric pressure)

Supply amount of oxygen: 500 sccm (0° C., 1 atmospheric pressure)

Vacuum level within vacuum chamber: 3 Pa

Application voltage from power source for generating plasma: 0.8 kW

Frequency of power source for generating plasma: 70 kHz Film conveyance speed: 1.0 m/min.

### Comparative Example 1-1

### Preparation of Gas Barrier Film 1-1

As a substrate, a transparent resin substrate having a hard coat layer (intermediate layer) (polyethylene terephthalate (PET) film having a clear hard coat layer (CHC) manufactured by KIMOTO CO., Ltd.) was prepared. On top of the substrate, only a second barrier layer was directly formed. The second barrier layer was prepared as follows: a dibutyl ether solution containing 20% by weight of perhydropolysilazane (AQUAMICA (registered trademark) NN120-20 manufacturedbyAZ ELECTRONIC MATERIALS) was diluted to 5% by weight by dibutyl ether to prepare a coating liquid, a polysilazane coating film was formed to have thickness of 150 nm by using the coating liquid, and then a vacuum ultraviolet ray irradiation treatment was performed in the same manner as the forming of a first barrier layer (coating method) described above with irradiation amount of 6000 mJ/cm² at dew point of 0° C. to form a second barrier layer. Accordingly, the gas barrier film 1-1 was prepared.

### Comparative Example 1-2

### Preparation of Gas Barrier Film 1-2

The second barrier film was prepared in the same manner as Comparative Example 1-1 except that, as an amine catalyst, N,N,N′,N′-tetramethyl-1,6-diaminohexane (TMDAH)) is added in an amount of 1% by weight relative to perhydropolysilazane and the dew point for ultraviolet ray irradiation treatment is changed to −30° C. Accordingly, the gas barrier film 1-2 was prepared.

### Comparative Example 1-3

### Preparation of Gas Barrier Film 1-3

As a substrate, a transparent resin substrate having a hard coat layer (intermediate layer) (polyethylene terephthalate (PET) film having a clear hard coat layer (CHC) manufactured by KIMOTO CO., Ltd.) was prepared. On top of the substrate, a first barrier layer was formed according to the “forming of a first barrier layer (coating method)” described above. After that, the second barrier layer was formed on top of the first barrier layer in the same manner as Comparative Example 1-1 to prepare the gas barrier film 1-3.

### Comparative Example 1-4

### Preparation of Gas Barrier Film 1-4

As a substrate, a transparent resin substrate having a hard coat layer (intermediate layer) (polyethylene terephthalate (PET) film having a clear hard coat layer (CHC) manufactured by KIMOTO CO., Ltd.) was prepared. On top of the substrate, a first barrier layer was formed according to the “forming of a first barrier layer (coating method)” described above. After that, the second barrier layer was formed on top of the first barrier layer in the same manner as Comparative Example 1-2 to prepare the gas barrier film 1-4.

### Comparative Example 1-5

### Preparation of Gas Barrier Film 1-5

As a substrate, a transparent resin substrate having a hard coat layer (intermediate layer) (polyethylene terephthalate (PET) film having a clear hard coat layer (CHC) manufactured by KIMOTO CO., Ltd.) was prepared. On top of the substrate, a first barrier layer was formed according to the “forming of a first barrier layer (plasma CVD method)” described above. After that, the second barrier layer was formed on top of the first barrier layer in the same manner as Comparative Example 1-1 to prepare the gas barrier film 1-5.

### Comparative Example 1-6

### Preparation of Gas Barrier Film 1-6

As a substrate, a transparent resin substrate having a hard coat layer (intermediate layer) (polyethylene terephthalate (PET) film having a clear hard coat layer (CHC) manufactured by KIMOTO CO., Ltd.) was prepared. On top of the substrate, a first barrier layer was formed according to the “forming of a first barrier layer (plasma CVD method)” described above. After that, the second barrier layer was formed on top of the first barrier layer in the same manner as Comparative Example 1-2 to prepare the gas barrier film 1-6.

### Comparative Example 1-7

### Preparation of Gas Barrier Film 1-7

The gas barrier film 1-7 was prepared in the same manner as Comparative Example 1-6 except that the second barrier layer is formed as described below.

The coating liquid was prepared as follows: a dibutyl ether solution containing 20% by weight perhydropolysilazane (AQUAMICA (registered trademark) NN120-20, produced by AZ electronic materials Co., Ltd.) was diluted to concentration of 5% by weight with dibutyl ether, and as an amine catalyst, N,N,N′,N′-tetramethyl-1,6-diaminohexane (TMDAH) was added to have an amount of 1% by weight and also water was added to have an amount of 5% by weight. By using the coating liquid, a polysilazane coating film having thickness of 150 nm was prepared. After that, by performing a vacuum ultraviolet ray irradiation with irradiation amount of 6000 mJ/cm² at dew point of −30° C. in the same manner as the forming of a first barrier layer (coating method) described above, a second barrier layer was formed.

### Example 1-1

### Preparation of Gas Barrier Film 1-8

The gas barrier film 1-8 was prepared in the same manner as Comparative Example 1-7 except that the amount of water is changed to an amount of 10% by weight relative to perhydropolysilazane.

### Comparative Example 1-8

### Preparation of Gas Barrier Film 1-9

The gas barrier film 1-9 was prepared in the same manner as Comparative Example 1-7 except that, instead of water, methanol (Cica first grade, manufactured by Kanto Chemical Co., Inc.) is added in an amount of 1% by weight relative to perhydropolysilazane.

### Example 1-2

### Preparation of Gas Barrier Film 1-10

The gas barrier film 1-10 was prepared in the same manner as Comparative Example 1-8 except that the amount of methanol is changed to an amount of 5% by weight relative to perhydropolysilazane.

### Example 1-3

### Preparation of Gas Barrier Film 1-11

The gas barrier film 1-11 was prepared in the same manner as Comparative Example 1-8 except that the amount of methanol is changed to an amount of 10% by weight relative to perhydropolysilazane.

### Comparative Example 1-9

### Preparation of Gas Barrier Film 1-12

The gas barrier film 1-12 was prepared in the same manner as Comparative Example 1-7 except that, instead of water, ALCH (aluminum ethylacetoacetate•diisopropylate manufactured by Kawaken Fine Chemicals Co., Ltd.) is added in an amount of 1% by weight relative to perhydropolysilazane.

### Example 1-4

### Preparation of Gas Barrier Film 1-13

The gas barrier film 1-13 was prepared in the same manner as Comparative Example 1-9 except that the amount of ALCH is changed to an amount of 2% by weight relative to perhydropolysilazane.

### Example 1-5

### Preparation of gas barrier film 1-14

The gas barrier film 1-14 was prepared in the same manner as Comparative Example 1-9 except that the amount of ALCH is changed to an amount of 4% by weight relative to perhydropolysilazane.

### Example 1-6

### Preparation of Gas Barrier Film 1-15

The gas barrier film 1-15 was prepared in the same manner as Comparative Example 1-7 except that, instead of water, AMD (aluminum diisopropylate•monosecondary butyrate manufactured by Kawaken Fine Chemicals Co., Ltd.) is added in an amount of 1% by weight relative to perhydropolysilazane.

### Example 1-7

### Preparation of Gas Barrier Film 1-16

The gas barrier film 1-16 was prepared in the same manner as Comparative Example 1-7 except that the amount of AMD is changed to an amount of 2% by weight relative to perhydropolysilazane.

### Example 1-8

### Preparation of Gas Barrier Film 1-17

The gas barrier film 1-17 was prepared in the same manner as Comparative Example 1-7 except that the amount of AMD is changed to an amount of 4% by weight relative to perhydropolysilazane.

### Comparative Example 1-10

### Preparation of Gas Barrier Film 1-18

The gas barrier film 1-18 was prepared in the same manner as Comparative Example 1-7 except that, instead of water, X-40-9225 (polymethylsilsesquioxane derivative having an alkoxysilyl group at molecular terminal, manufactured by Shin-Etsu Chemical Co., Ltd.) is added to a coating liquid in an amount of 1% by weight relative to perhydropolysilazane.

### Example 1-9

### Preparation of Gas Barrier Film 1-19

The gas barrier film 1-19 was prepared in the same manner as Comparative Example 1-7 except that the amount of X-40-9225 is changed to an amount of 2% by weight relative to perhydropolysilazane.

### Example 1-10

### Preparation of Gas Barrier Film 1-20

The gas barrier film 1-20 was prepared in the same manner as Comparative Example 1-7 except that the amount of X-40-9225 is changed to an amount of 4% by weight relative to perhydropolysilazane.

### Comparative Example 1-11

### Preparation of Gas Barrier Film 1-21

The gas barrier film 1-21 was prepared in the same manner as Comparative Example 1-9 except that the first barrier is formed as described below.

[Forming of a First Barrier Layer (Sputtering Method)]

A transparent resin substrate applied with a clear hard coat layer (intermediate layer) (polyethylene terephthalate (PET) film having a clear hard coat layer (CHC), manufactured by KIMOTO CO., Ltd.) was set in a vacuum chamber of a sputtering apparatus manufactured by ULVAC, Inc., followed by air purge to 10⁻⁴ Pa. Then, argon was introduced as discharge gas with partial pressure of 0.5 Pa. When the atmospheric pressure is stabilized, discharge was started to generate plasma on a silicon oxide (SiOₓ) target and the sputtering process was started. When the process is stabilized, the shutter was open to start forming silicon oxide film (SiOₓ) on the film. When the film of 100 nm was deposited, the shutter was closed to terminate the film forming and thus a first barrier layer was formed.

### Example 1-11

### Preparation of Gas Barrier Film 1-22

The gas barrier film 1-22 was prepared in the same manner as Example 1-5 except that the first barrier is formed as the method of “forming of a first barrier layer (sputtering method)” described above.

### Example 1-12

### Preparation of Gas Barrier Film 1-23

The gas barrier film 1-23 was prepared in the same manner as Example 1-6 except that the first barrier is formed as the method of “forming of a first barrier layer (sputtering method)” described above.

<<Evaluation of Film Composition Atomic Ratio (Profile of O/Si and N/Si in Depth Direction>>

Based on the apparatus and conditions described below, O/Si and N/Si were obtained from the average profile value in depth direction for the second barrier layer of a gas barrier film prepared above, and it was shown in Table 1.

(Sputtering conditions)

Ion species: Ar ion

Acceleration voltage: 1 kV

(Measurement conditions for X ray photoelectron spectroscopy)

Apparatus: ESCALAB-200R manufactured by VG Scientifix Co., Ltd.

X ray anode material: Mg

Output: 600 W (acceleration voltage: 15 kV, emission current: 40 mA)

Meanwhile, the measurement resolution was 0.5 nm and each atomic ratio was plotted for each sampling point according to the resolution.

(FIB Processing)

Apparatus: SMI2050 manufactured by SII

Processing ion: (Ga 30 kV)

(TEM Measurement)

Apparatus: JEM2000FX manufactured by JEOL Ltd. (acceleration voltage: 200 kV)

Time for electron beam irradiation: 5 seconds to 60 seconds

(Atomic Ratio in Depth Direction of Film Thickness from Surface of a Second Barrier Layer)

By comparing the XPS measurement (specifically, Si, O, and N) at each depth which is obtained by sputtering from a second barrier layer as described above and the results obtained from cross-sectional surface observation by TEM, the average value of O/Si and N/Si was calculated.

Furthermore, in the same manner as above, an average abundance ratio of oxygen atoms to silicon atoms in a region from the outermost surface to a depth of 10 nm (“O/Si surface” column in Table 1), an average abundance ratio of oxygen atoms to silicon atoms in a region from the outermost surface to a depth of more than 10 nm (“O/Si inside” column in Table 1), an average abundance ratio of nitrogen atoms to silicon atoms in a region from the outermost surface to a depth of 10 nm (“N/Si surface” column in Table 1), and an average abundance ratio of nitrogen atoms to silicon atoms in a region from the outermost surface to a depth of more than 10 nm (“N/Si inside” column in Table 1) were measured. Furthermore, a difference between an average abundance ratio of oxygen atoms to silicon atoms in a region from the outermost surface to a depth of 10 nm and an average abundance ratio of oxygen atoms to silicon atoms in a region from the outermost surface to a depth of more than 10 nm was calculated (“O/Si difference between surface and inside” column in Table 1),

<<Evaluation of Water Vapor Barrier Property>>

With the gas barrier film which has been prepared in the above, each sample which has been exposed for 1000 hours under high temperature and high moister conditions of 85° C., 85% RH (sample after deterioration test) was prepared.

Evaluation of a water vapor barrier property was performed as follows: metal calcium with thickness of 80 nm was vapor-deposited on a gas barrier film and the time for the calcium formed as a film to have an area of 50% was evaluated as 50% area time (see below). The 50% area time before and after deterioration test was evaluated, and the ratio of 50% area time after deterioration test/50% area time before deterioration test was calculated as retention rate (%) and shown in Table 1. As criteria of the retention rate, 70% or more was determined as acceptable and less than 70% was determined as unacceptable.

(Apparatus for Forming Metal Calcium Film)

Deposition apparatus: Vacuum deposition apparatus JEE-400 manufactured by JEOL, Ltd.

Constant temperature and humidity oven: Yamato Humidic Chamber IG 47 M.

(Raw Material)

Metal to be corroded by reaction with moisture: calcium (particle)

Water vapor impermeable metal: aluminum (: 3 to 5 mm, particle)

(Preparation of Sample for Evaluating Water Vapor Barrier Property)

A second barrier layer surface of the manufactured barrier film was vapor-deposited with metal calcium to have a size of 12 mm×12 mm via a mask by using a vacuum deposition apparatus (vacuum vapor deposition apparatus JEE-400 made by JEOL, Ltd.). At that time, vapor-deposited film thickness was adjusted to 80 nm.

Thereafter, the mask was removed while keeping the vacuum condition, and aluminum was deposited on a whole one surface of the sheet to have temporary sealing. Subsequently, the vacuum condition was removed. After immediate transfer to a dry nitrogen gas atmosphere, a quartz glass having a thickness of 0.2 mm was adhered onto the aluminum vapor-deposited surface using an ultraviolet curing resin for sealing (manufactured by Nagase ChemteX Co., Ltd.), and ultraviolet ray were irradiated for adhesion and curing of the resin to have main sealing. As a result, a sample for evaluating water vapor barrier property was prepared.

The obtained sample was stored under high temperature and high humidity condition of 85° C. and 85% RH and a state of having corrosion of the metal calcium was observed over the storage time. Then, the time of having 50% corroded area of metal calcium against the 12 mm×12 mm metal calcium deposited-area was interpolated as a straight line from the observation result and the result before and after the deterioration test was shown in Table 1.

Evaluation results of the gas barrier film of each Example and each Comparative Example is shown in the following Table 1.

TABLE 1

| | | First barrier layer | Second barrier layer | | | | | | | Water vapor barrier property (hr) | | |
|---|---|---|---|---|---|---|---|---|---|---|---|---|
| | | (containing Si | | Dew point of | | | | | O/Si difference | | After | |
| | Film | compound) | | ultraviolet ray | | | | | between surface and | Before | deterioration | Retention rate |
| | No. | Forming method | additive | irradiation | O/Si surface | N/Si surface | O/Si inside | N/Si inside | inside | deterioration test | test | (%) |
| Comparative | 1-1 | None | None | 0 C.° | 0.6 | 0.6 | 2.2 | 0 | 1.6 | 24 | 1 | 4 |
| Example 1-1 | | | | | | | | | | | | |
| Comparative | 1-2 | None | TMDAH 1% | −30 C.° | 0.8 | 0.5 | 2.2 | 0 | 1.4 | 48 | 1 | 2 |
| Example 1-2 | | | | | | | | | | | | |
| Comparative | 1-3 | Coating method | None | 0 C.° | 0.8 | 0.5 | 0.6 | 0.6 | 0.2 | 100 | 1 | 1 |
| Example 1-3 | | | | | | | | | | | | |
| Comparative | 1-4 | Coating method | TMDAH 1% | −30 C.° | 1.5 | 0.3 | 0.3 | 0.7 | 1.2 | 200 | 12 | 6 |
| Example 1-4 | | | | | | | | | | | | |
| Comparative | 1-5 | Plasma CVD | None | 0 C.° | 0.8 | 0.5 | 0.6 | 0.6 | 0.2 | 150 | 1 | 1 |
| Example 1-5 | | | | | | | | | | | | |
| Comparative | 1-6 | Plasma CVD | TMDAH 1% | −30 C.° | 1.5 | 0.3 | 0.3 | 0.7 | 1.2 | 200 | 24 | 12 |
| Example 1-6 | | | | | | | | | | | | |
| Comparative | 1-7 | Plasma CVD | TMDAH 1% + H₂O 5% | −30 C.° | 2.0 | 0.1 | 1.0 | 0.5 | 1.0 | 150 | 48 | 32 |
| Example 1-7 | | | | | | | | | | | | |
| Example 1-1 | 1-8 | Plasma CVD | TMDAH 1% + H₂O 10% | −30 C.° | 2.0 | 0.1 | 1.4 | 0.4 | 0.6 | 200 | 150 | 75 |
| Comparative | 1-9 | Plasma CVD | MEOH 1% | −30 C.° | 2.1 | 0 | 1.0 | 0.5 | 1.1 | 200 | 100 | 50 |
| Example 1-8 | | | | | | | | | | | | |
| Example 1-2 | 1-10 | Plasma CVD | MEOH 5% | −30 C.° | 2.1 | 0 | 1.5 | 0.3 | 0.6 | 400 | 280 | 70 |
| Example 1-3 | 1-11 | Plasma CVD | MEOH 10% | −30 C.° | 2.2 | 0 | 1.7 | 0.2 | 0.5 | 350 | 250 | 71 |
| Comparative | 1-12 | Plasma CVD | ALCH 1% | −30 C.° | 1.5 | 0.3 | 1.3 | 0.4 | 0.2 | 400 | 200 | 50 |
| Example 1-9 | | | | | | | | | | | | |
| Example 1-4 | 1-13 | Plasma CVD | ALCH 2% | −30 C.° | 1.9 | 0.1 | 1.7 | 0.2 | 0.2 | 500 | 450 | 90 |
| Example 1-5 | 1-14 | Plasma CVD | ALCH 4% | −30 C.° | 2.2 | 0 | 2.0 | 0 | 0.2 | 600 | 600 | 100 |
| Example 1-6 | 1-15 | Plasma CVD | AMD 1% | −30 C.° | 1.5 | 0.3 | 1.4 | 0.3 | 0.1 | 400 | 320 | 80 |
| Example 1-7 | 1-16 | Plasma CVD | AMD 2% | −30 C.° | 2.1 | 0 | 2.0 | 0 | 0.1 | 600 | 700 | 117 |
| Example 1-8 | 1-17 | Plasma CVD | AMD 4% | −30 C.° | 2.2 | 0 | 2.1 | 0 | 0.1 | 500 | 500 | 100 |
| Comparative | 1-18 | Plasma CVD | X-40-9225 1% | −30 C.° | 1.3 | 0.4 | 0.8 | 0.5 | 0.5 | 220 | 100 | 45 |
| Example | | | | | | | | | | | | |
| 1-10 | | | | | | | | | | | | |
| Example 1-9 | 1-19 | Plasma CVD | X-40-9225 2% | −30 C.° | 1.9 | 0.1 | 1.4 | 0.3 | 0.5 | 400 | 300 | 75 |
| Example 1-10 | 1-20 | Plasma CVD | X-40-9225 4% | −30 C.° | 2.0 | 0 | 1.5 | 0.2 | 0.5 | 400 | 280 | 70 |
| Comparative | 1-21 | Sputter | ALCH 1% | −30 C.° | 1.5 | 0.3 | 1.3 | 0.4 | 0.2 | 400 | 200 | 50 |
| Example | | | | | | | | | | | | |
| 1-11 | | | | | | | | | | | | |
| Example 1-11 | 1-22 | Sputter | ALCH 2% | −30 C.° | 1.9 | 0.1 | 1.7 | 0.2 | 0.2 | 500 | 450 | 90 |
| Example 1-12 | 1-23 | Sputter | ALCH 4% | −30 C.° | 2.2 | 0 | 2.0 | 0 | 0.2 | 600 | 600 | 100 |

As it is evident from Table 1, the gas barrier film manufactured in Examples of the present invention clearly has almost no decrease in the gas barrier property accompanied with composition change even when it is exposed to high temperature and high moisture conditions for a long period of time.

Thus, it was found from Table 1 that the gas barrier film according to the present invention has excellent storage stability, in particular, storage stability under harsh conditions (high temperature and high moisture conditions).

Meanwhile, the second barrier layer of the present invention exhibited O/Si of 1.4 to 2.2 and N/Si of 0 to 0.4 when the measurement was made at any point in angle depth direction which is obtained by sputtering (XPS) from a surface of the second barrier layer.

<<Production of Organic Thin Film Electronic Device>>

By using the gas barrier film 1-1 to 1-23 as a sealing film, an organic EL element, which is an organic thin film electronic device, was produced.

[Production of Organic EL Element]

(Forming of First Electrode Layer)

On the second barrier layer of each gas barrier film, ITO (indium tin oxide) film with thickness of 150 nm was formed by a sputtering method, and by performing patterning by photolithography, a first electrode layer was formed. Meanwhile, the pattern was formed to be a pattern having a light emitting area of 50 mm².

(Forming of Hole Transport Layer)

On the top of the first electrode layer of each gas barrier film having the first electrode layer formed thereon, the following coating liquid for forming a hole transport layer was coated using an extrusion coater under an environment of 25° C., and relative humidity of 50% RH, and a hole transport layer was formed by drying and heating treatment under the following conditions. The coating liquid for forming a hole transport layer was coated such that the thickness after drying is 50 nm.

Before applying the coating liquid for forming a hole transport layer, a treatment for modifying a cleaned surface of the gas barrier film was performed at irradiation intensity of 15 mW/cm² and distance of 10 mm by using a low pressure mercury lamp with wavelength of 184.9 nm. The antistatic treatment was performed by using a neutralizer having weak X ray.

<Preparation of Coating Liquid for Forming Hole Transport Layer>

A solution obtained by diluting polyethylene dioxythiophene•polystyrene sulfonate (PEDOT/PSS, Bytron P AI 4083 manufactured by Bayer) with to 65% with pure water, 5% with methanol was prepared as a coating liquid for forming a hole transport layer.

<Condition for Drying and Heating Treatment>

After applying the coating liquid for forming a hole transport layer, the solvent was removed at temperature of 100° C. with air from height of 100 mm, discharge air speed of 1 m/s, and width air speed distribution of 5% toward the formed film surface. Subsequently, by using an apparatus for heating treatment, a heating treatment based on backside electric heating mode was performed at 150° C. to forma hole transport layer.

(Forming of Light Emitting Layer)

Subsequently, on the top of the hole transport layer formed above, a coating liquid for forming a white light emitting layer described below was coated under the following conditions by using an extrusion coater, and an light emitting layer was formed by drying and heating treatment under the following conditions. The coating liquid for forming a white light emitting layer was coated such that the thickness after drying is 40 nm.

<Coating Liquid for Forming White Light Emitting Layer>

1.0 g of a compound represented by the following formula H-A as a host material, 100 mg of a compound represented by the following formula D-A as a dopant material, 0.2 mg of a compound represented by the following formula D-B as a dopant material, and 0.2 mg of a compound represented by the following formula D-C as a dopant material were dissolved in 100 g toluene to prepare a coating liquid for forming a white light emitting layer.

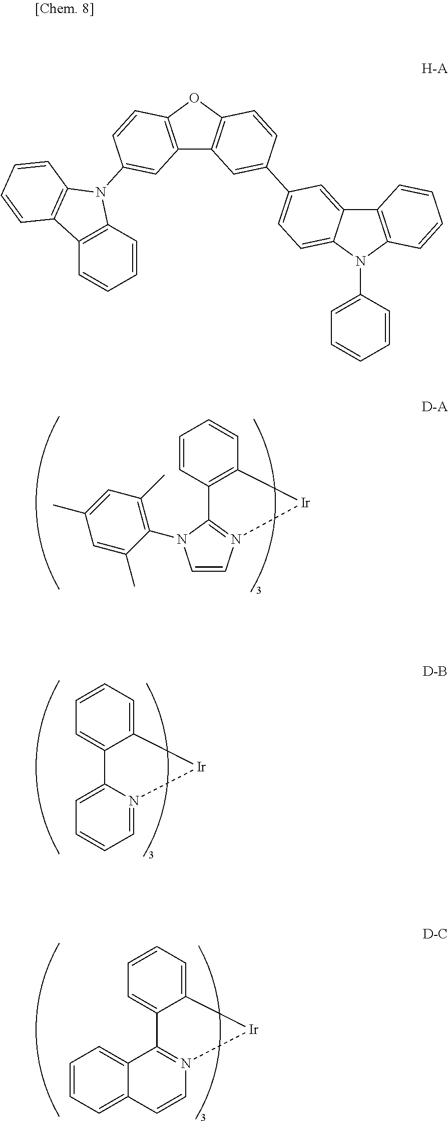

<Coating Condition>

The coating process was performed under an environment with nitrogen gas concentration of 99% or more, temperature of 25° C. and coating speed of 1 m/min.

<Condition for Drying and Heating Treatment>

After applying the coating liquid for forming a white light emitting layer, the solvent was removed at temperature of 60° C. with air from height of 100 mm, discharge air speed of 1 m/s, and width air speed distribution of 5% toward the formed film surface. Subsequently, according to a heating treatment at the temperature of 130° C., a light emitting layer was formed.

(Forming of Electron Transport Layer)

Subsequently, on top of the light emitting layer produced above, the following coating liquid for forming an electron transport layer was coated using an extrusion coater under the following conditions, and an electron transport layer was formed by drying and a heating treatment under the following conditions. The coating liquid for forming an electron transport layer was coated such that the thickness after drying is 30 nm.

<Coating Condition>

The coating process was performed under an environment with nitrogen gas concentration of 99% or more, and coating temperature of 25° C. and coating speed of 1 m/min for the coating liquid for forming an electron transport layer.

<Coating Liquid for Forming Electron Transport Layer>

As for the electron transport layer, a compound represented by the following formula E-A was dissolved in 2,2,3,3-tetrafluoro-1-propanol to obtain a 0.5% by weight solution, which was then used as a coating liquid for forming an electron transport layer.

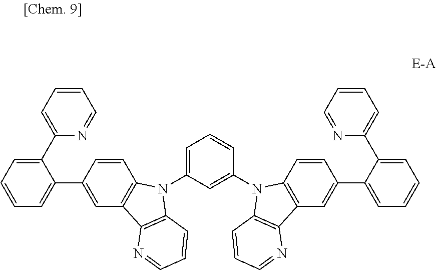 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

<Condition for Drying and Heating Treatment>

After applying the coating liquid for forming an electron transport layer, the solvent was removed at temperature of 60° C. with air from height of 100 mm, discharge air speed of 1 m/s, and width air speed distribution of 5% toward the formed film surface. Subsequently, according to a heating treatment at the temperature of 200° C. in a heating treatment part, an electron transport layer was formed.

(Forming of Electron Injection Layer)

Subsequently, an electron injection layer was formed on the top of the electron transport layer which has been formed as described above. First, the substrate was added into a chamber under reduced pressure, and the pressure was lowered to 5×10⁻⁴ Pa. By heating cesium fluoride which has been prepared in advance in a tantalum deposition boat within a vacuum chamber, an electron injection layer having a thickness of 3 nm was formed.

(Forming of Second Electrode)

Subsequently, on top of the electron injection layer, a mask pattern film forming was formed to have a light emitting area of 50 mm² by using aluminum as a material for forming a second electrode under vacuum of 5×10⁻⁴ Pa and vapor deposition method to have an extraction electrode, excluding a region to be an extraction electrode of the first electrode 22. As a result, the second electrode having a thickness of 100 nm was laminated.

(Cutting)

Each layered product formed up to the second electrode was transferred again to a nitrogen atmosphere, and cut to a pre-determined size by using ultraviolet laser to manufacture an organic EL element.

(Attachment of Electrode Lead)

To the manufactured organic EL element, a flexible print substrate (base film: polyimide 12.5 μm, pressed copper foil 18 μm, coverlay: polyimide 12.5 μm, surface treatment: NiAu plating) was attached by using an anisotropic conductive film DP3232S9 manufactured by Sony Chemical and Information Device Corporation.

Compression condition: compression was performed for 10 seconds at temperature of 170° C. (ACF temperature of 140° C. measured by using a thermocouple separately) and pressure of 2 MPa.

(Sealing)

Meanwhile, as a sealing member, a 30 μm thick aluminum foil (manufactured by TOYO ALUMINIUM K.K.) laminated with a polyethylene terephthalate (PET) film (12 μm thick) by using adhesive for dry lamination (two-liquid reaction type urethane-based adhesive) was used (thickness of adhesive layer: 1.5 μm).

A thermosetting adhesive was uniformly coated on an aluminum surface of the prepared sealing member to have a thickness of 20 μm along the surface attached with an aluminum foil (glossy surface) by using a dispenser.

At that time, as the thermosetting adhesive, the following epoxy-based adhesive containing the following components was used.

Bisphenol A diglycidyl ether (DGEBA), Dicyandiamide (DICY), Epoxy adduct-based curing promoter

After that, the sealed substrate was closely attached and placed such that the connection part between the extraction electrode and the electrode lead is covered. Then, it was tightly sealed by using a compression roll with compression condition including compression roll temperature of 120° C., pressure of 0.5 MPa, and apparatus speed of 0.3 m/min.

<<Evaluation of Organic EL Element>>

The organic EL elements manufactured above were subjected to durability evaluation according to the method described below.

[Durability Evaluation]

(Accelerated Deterioration Treatment)

Each organic EL element manufactured above was subjected to an accelerated deterioration treatment for 500 hours under atmosphere of 85° C. and 85% RH. Thereafter, the following evaluation test regarding dark spots was performed.

(Evaluation of Dark Spots (DS, Black Spots))

The organic EL element after the accelerated deterioration treatment was applied with electric current of 1 mA/cm². After continuous light emission for 24 hours, a part of the panel was enlarged by using 100x microscope (MS-804 manufactured by MORITEX CORPORATION, lens: MP-ZE25-200), and a photographic image was taken. After cutting the photographed image to a 2 mm square, the ratio of an area having dark spots was obtained and the durability was then evaluated according to the following criteria. Determinations were made as follows: when the evaluated rank is Δ, it was found to be a practical characteristic, when the evaluated rank is ◯, it was found to be a more practical characteristic, and when the evaluated rank is ⊙, it was found to be a preferred characteristic without have any problem at all.

⊙: Occurrence rate of dark spots is less than 0.3%

◯: Occurrence rate of dark spots is 0.3% or more and less than 1.0%

Δ: Occurrence rate of dark spots is 1.0% or more and less than 2.0%

X: Occurrence rate of dark spots is 2.0% or more and less than 5.0%

XX: Occurrence rate of dark spots is 5.0% or more

The results obtained from evaluation of dark spots are described in Table 2 below.

TABLE 2

| | Organic EL | | |
|---|---|---|---|
| | element | Film No. | DS evaluation |
| Comparative | 2-1 | 1-1 | XX |
| Example 1-1 | | | |
| Comparative | 2-2 | 1-2 | XX |
| Example 1-2 | | | |
| Comparative | 2-3 | 1-3 | XX |
| Example 1-3 | | | |
| Comparative | 2-4 | 1-4 | XX |
| Example 1-4 | | | |
| Comparative | 2-5 | 1-5 | XX |
| Example 1-5 | | | |
| Comparative | 2-6 | 1-6 | X |
| Example 1-6 | | | |
| Comparative | 2-7 | 1-7 | X |
| Example 1-7 | | | |
| Example 1-1 | 2-8 | 1-8 | Δ |
| Comparative | 2-9 | 1-9 | X |
| Example 1-8 | | | |
| Example 1-2 | 2-10 | 1-10 | Δ |
| Example 1-3 | 2-11 | 1-11 | Δ |
| Comparative | 2-12 | 1-12 | X |
| Example 1-9 | | | |
| Example 1-4 | 2-13 | 1-13 | ◯ |
| Example 1-5 | 2-14 | 1-14 | ⊙ |
| Example 1-6 | 2-15 | 1-15 | ◯ |
| Example 1-7 | 2-16 | 1-16 | ⊙ |
| Example 1-8 | 2-17 | 1-17 | ◯ |
| Comparative | 2-18 | 1-18 | X |
| Example 1-10 | | | |
| Example 1-9 | 2-19 | 1-19 | Δ |
| Example 1-10 | 2-20 | 1-20 | Δ |
| Comparative | 2-21 | 1-21 | X |
| Example 1-11 | | | |
| Example 1-11 | 2-22 | 1-22 | ◯ |
| Example 1-12 | 2-23 | 1-23 | ⊙ |

As clearly shown in the results described in Table 2, it was found that the gas barrier film manufactured in Examples of the present invention has an effect of reducing an occurrence of dark spots when used as a sealing film of an organic EL element, and it has a very high gas barrier property.

Meanwhile, the present application is based on Japanese Patent Application No. 2013-017257 filed on Jan. 31, 2013, and its disclosure is incorporated herein by reference in its entirety.

1. A gas barrier film comprising, in order:
a substrate;
a first barrier layer which comprises an inorganic compound; and
a second barrier layer which comprises at least silicon atoms and oxygen atoms, which has an abundance ratio of oxygen atoms to silicon atoms (O/Si) of 1.4 to 2.2, and which has an abundance ratio of nitrogen atoms to silicon atoms (N/Si) of 0 to 0.4.

2. The gas barrier film according to claim 1, wherein a difference between an average abundance ratio of oxygen atoms to silicon atoms in a region from the outermost surface to a depth of 10 nm and an average abundance ratio of oxygen atoms to silicon atoms in a region from the outermost surface to a depth of more than 10 nm is 0.4 or less in the second barrier layer.

3. The gas barrier film according to claim 1, wherein the second barrier layer is formed by a conversion treatment based on active energy ray irradiation of a layer comprising polysilazane and at least one compound selected from the group consisting of an alcohol compound, a phenol compound, a metal alkoxide compound, an alkylamine compound, alcohol modified polysiloxane, alkoxy modified polysiloxane, and alkylamino modified polysiloxane.

4. The gas barrier film according to claim 1, wherein the first barrier layer is formed by a chemical vapor phase growing method or a physical vapor phase growing method.

5. An organic EL element comprising a gas barrier film described in claim 1.

6. The gas barrier film according to claim 2, wherein the second barrier layer is formed by a conversion treatment based on active energy ray irradiation of a layer comprising polysilazane and at least one compound selected from the group consisting of an alcohol compound, a phenol compound, a metal alkoxide compound, an alkylamine compound, alcohol modified polysiloxane, alkoxy modified polysiloxane, and alkylamino modified polysiloxane.

7. The gas barrier film according to claim 2, wherein the first barrier layer is formed by a chemical vapor phase growing method or a physical vapor phase growing method.

8. The gas barrier film according to claim 3, wherein the first barrier layer is formed by a chemical vapor phase growing method or a physical vapor phase growing method.

9. The gas barrier film according to claim 6, wherein the first barrier layer is formed by a chemical vapor phase growing method or a physical vapor phase growing method.

10. An organic EL element comprising a gas barrier film described in claim 2.

11. An organic EL element comprising a gas barrier film described in claim 3.

12. An organic EL element comprising a gas barrier film described in claim 4.

13. An organic EL element comprising a gas barrier film described in claim 6.

14. An organic EL element comprising a gas barrier film described in claim 7.

15. An organic EL element comprising a gas barrier film described in claim 8.

16. An organic EL element comprising a gas barrier film described in claim 9.
